(19) United States
(12) Patent Application Publication
(10) Pub. No.: US 2014/0184810 A1
(43) Pub. Date: Jul. 3, 2014

(54) INSPECTION SYSTEM, INSPECTION METHOD, PIXEL CIRCUIT AND IMAGE SENSOR

(71) Applicant: ROHM CO., LTD., Kyoto (JP)

(72) Inventor: Hiroshi SEKIGUCHI, Kyoto (JP)

(73) Assignee: ROHM CO., LTD., Kyoto (JP)

(21) Appl. No.: 14/140,990

(22) Filed: Dec. 26, 2013

(30) Foreign Application Priority Data
Dec. 27, 2012 (JP) 2012-284885

(51) Int. Cl. G01N 21/95; H04N 5/33; H01L 27/146

(52) U.S. Cl. CPC G01N 21/9501; H01L 27/14612; H04N 5/332
USPC 348/164; 250/214 P

(57) ABSTRACT

An inspection system includes a CIGS camera configured to generate a visible light image and an infrared light image of an inspection object by imaging visible light and infrared light simultaneously on the same optical axis using a CIGS image sensor, and an inspection apparatus configured to inspect the inspection object based on the visible light image and the infrared light image.

### CROSS-REFERENCE TO RELATED APPLICATIONS

This application is based upon and claims the benefit of priority from Japanese Patent Applications No. 2012-284885, filed on Dec. 27, 2012, the entire contents of which are incorporated herein by reference.

### TECHNICAL FIELD

The present disclosure relates to an inspection system, an inspection method, a pixel circuit and an image sensor.

### BACKGROUND

There are techniques for allowing a solar cell to emit EL (Electro-Luminescence) light and inspecting the quality of the solar cell from its emission state. In addition, a cooled CCD (Charge Coupled Device) camera can be used to detect visible light or an InGaAs camera using InGaAs as material for detecting near-infrared light for inspection of a solar cell.

However, the aforementioned techniques require two cameras, i.e., the cooled CCD camera and the InGaAs camera, in order to image both visible light and near-infrared light. That is, the cooled CCD camera cannot detect the near-infrared light although it can detect the visible light. On the other hand, the InGaAs camera cannot detect the visible light although it can detect the near-infrared light. In addition, the use of these two cameras may produce a deviation in optical axis between these two cameras, which may result in a deviation between a visible light image and an infrared light image.

### SUMMARY

The present disclosure provides some embodiments of an inspection system which is capable of inspecting an inspection object with convenience and high precision, an inspection method, a pixel circuit and an image sensor.

According to one embodiment of the present disclosure, an inspection system includes a CIGS camera configured to generate a visible light image and an infrared light image of an inspection object by imaging visible light and infrared light simultaneously on the same optical axis using a CIGS image sensor; and an inspection apparatus configured to inspect the inspection object based on the visible light image and the infrared light image.

According to another embodiment of the present disclosure, an inspection method includes generating a visible light image and an infrared light image of an inspection object by imaging visible light and infrared light simultaneously on the same optical axis using a CIGS image sensor; and inspecting the inspection object based on the visible light image and the infrared light image.

According to another embodiment of the present disclosure, a pixel circuit includes a photodiode; and a floating diffusion, wherein the pixel circuit outputs a voltage determined by an electric charge quantity transmitted from a parasitic capacitance of the photodiode to the floating diffusion and a capacitance of the photodiode.

According to another embodiment of the present disclosure, there is provided an image sensor having a pixel circuit performing image sensing on a pixel basis, wherein the pixel circuit includes: a photodiode; and a floating diffusion, and wherein the pixel circuit outputs a voltage determined by an electric charge quantity transmitted from a parasitic capacitance of the photodiode to the floating diffusion and a capacitance of the photodiode.

### BRIEF DESCRIPTION OF THE DRAWINGS

FIGS. 1A and 1B are schematic circuit diagrams of an inspection system according to a first embodiment of the present disclosure, FIG. 1A showing the entire system configuration and FIG. 1B showing an ISP configuration.

FIG. 2 is a schematic bird's eyes view showing how to inspect solar panels by the inspection system according to the first embodiment.

FIG. 3 is a view showing a crystalline structure of CIGS used for the inspection system according to the first embodiment.

FIG. 4 is a graph showing a relationship between a wavelength and quantum efficiency of CIGS used in the inspection system according to the first embodiment.

FIGS. 5A and 5B are graphs used to explain EL light generated from the solar panel in the inspection system according to the first embodiment, FIG. 5A being a graph showing a relationship between an emission intensity and a wavelength of EL light and FIG. 5B being a graph showing a relationship between a quantum efficiency and a wavelength.

FIGS. 6A and 6B are views showing one example of the solar panel inspected by the inspection system according to the first embodiment, FIG. 6A being a schematic plane view of the solar panel and FIG. 6B being an infrared light image of the solar panel.

FIG. 7 is a flow chart showing an operation example of inspecting the solar panel by means of the inspection system according to the first embodiment.

FIG. 8 is a flow chart showing another operation example of inspecting the solar panel by means of the inspection system according to the first embodiment.

FIG. 9 is a flow chart showing still another operation example of inspecting the solar panel by means of the inspection system according to the first embodiment.

FIGS. 10A and 10B are schematic side views showing how to inspect an LSI by means of the inspection system according to the first embodiment, FIG. 10A showing a case of imaging the LSI from above and FIG. 10B showing a case of imaging the LSI from below.

FIGS. 11A and 11B are views showing one example of an LSI inspected by the inspection system according to the first embodiment, FIG. 11A being a schematic plane view and FIG. 11B being an infrared light image.

FIGS. 12A and 12B are views used to explain effects of the inspection system according to the first embodiment of the present disclosure, FIG. 12A showing a case of using two cameras, i.e., a cooled CCD camera and an InGaAs camera and FIG. 12B showing a case of using a CIGS camera.

FIG. 13 is a schematic circuit diagram of a CIGS image sensor used in the inspection system according to the first embodiment of the present disclosure.

FIG. 14 is a schematic circuit diagram of a pixel circuit of the CIGS image sensor for use in the inspection system according to the first embodiment of the present disclosure.

FIG. 15 is a timing chart showing example waveforms of a selection signal, a reset signal, a transmission signal, a node A, a node B and a node C, the waveforms representing temporal changes of voltages in the pixel circuit of the CIGS image sensor for use in the inspection system according to the first embodiment of the present disclosure.

FIG. 16 is a schematic circuit diagram of a photo-electric conversion circuit according to a comparative example.

FIG. 17 is a graph used to explain infrared light generated from an inspection object in an inspection system according to a second embodiment of the present disclosure.

FIGS. 18A and 18B are views showing one example of a soldering iron inspected by the inspection system according to the second embodiment of the present disclosure, FIG. 18A being a schematic bird's eye view and FIG. 18B being an infrared light image.

FIG. 19 is a flow chart showing an operation example of detecting heat by means of the inspection system according to the second embodiment of the present disclosure.

FIG. 20 is a schematic view showing the overall planar pattern configuration of a color solid state imaging device which can be applied to a CIGS image sensor for use in the inspection system according to the first or second embodiment of the present disclosure.

FIG. 21 is a schematic sectional view of the color solid state imaging device which can be applied to the CIGS image sensor for use in the inspection system according to the first or second embodiment of the present disclosure.

FIG. 22 is a schematic sectional view of a modification of the color solid state imaging device which can be applied to the CIGS image sensor for use in the inspection system according to the first or second embodiment of the present disclosure.

FIG. 23A is a view showing an array of color filters applied to the color solid state imaging device which can be applied to the CIGS image sensor for use in the inspection system according to the first or second embodiment of the present disclosure, and FIG. 23B is a view showing another array of color filters applied to the color solid state imaging device which can be applied to the CIGS image sensor for use in the inspection system according to the first or second embodiment of the present disclosure.

FIG. 24 is a view showing transmission characteristics of color filters applied to the color solid state imaging device which can be applied to the CIGS image sensor for use in the inspection system according to the first or second embodiment of the present disclosure.

FIG. 25 is a view showing the dependency of quantum efficiency on wavelengths for a compound semiconductor thin film applied to the color solid state imaging device which can be applied to the CIGS image sensor for use in the inspection system according to the first or second embodiment of the present disclosure.

FIG. 26 is a view showing light absorption characteristics of the compound semiconductor thin film applied to the color solid state imaging device which can be applied to the CIGS image sensor for use in the inspection system according to the first or second embodiment of the present disclosure.

FIG. 27A is a first schematic sectional view used to explain a first method for manufacturing the color solid state imaging device which can be applied to the CIGS image sensor for use in the inspection system according to the first or second embodiment of the present disclosure, and FIG. 27B is a second schematic sectional view used to explain the first method for manufacturing the color solid state imaging device which can be applied to the CIGS image sensor for use in the inspection system according to the first or second embodiment of the present disclosure.

FIG. 28 is a first schematic sectional view used to explain a second method for manufacturing the color solid state imaging device which can be applied to the CIGS image sensor for use in the inspection system according to the first or second embodiment of the present disclosure.

FIG. 29 is a second schematic sectional view used to explain the second method for manufacturing the color solid state imaging device which can be applied to the CIGS image sensor for use in the inspection system according to the first or second embodiment of the present disclosure.

FIGS. 30A and 30B are circuit diagrams of one pixel in the case of using avalanche multiplication and in the case of using no avalanche multiplication, respectively, in the color solid state imaging device which can be applied to the CIGS image sensor for use in the inspection system according to the first or second embodiment of the present disclosure.

FIG. 31 is a schematic circuit block diagram of the color solid state imaging device which can be applied to the CIGS image sensor for use in the inspection system according to the first or second embodiment of the present disclosure.

### DETAILED DESCRIPTION

Embodiments of the present disclosure will now be described in detail with reference to the drawings. Throughout the drawings, the same or similar elements are denoted by the same or similar reference numerals. It is however noted that the drawings are just schematic and relationships between thickness and planar dimension of elements, thickness ratios of various layers and so on may be unrealistic. Accordingly, detailed thickness and dimensions should be determined in consideration of the following description. In addition, it is to be understood that the figures include different dimensional relationships and ratios.

The following embodiments are provided to illustrate devices and methods to embody the technical ideas of the present disclosure and are not limited to materials, forms, structures, arrangements and so on of elements detailed herein. The embodiments of the present disclosure may be modified in different ways without departing from the spirit and scope of the invention defined in the claims.

### First Embodiment

### Inspection System

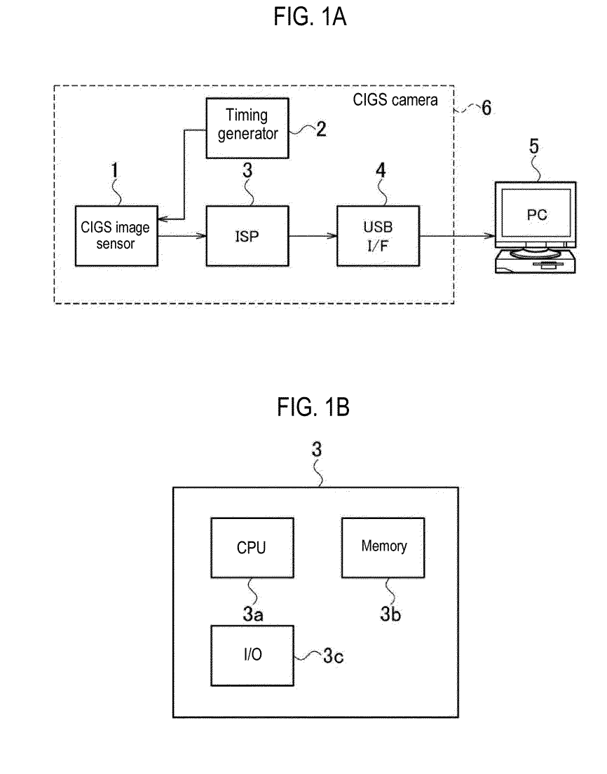

As shown in FIGS. 1A and 1B, an inspection system according to a first embodiment includes a CIGS (Copper Indium Gallium Selenide) camera 6 to generate a visible light image and an infrared light image for an inspection object by imaging visible light and infrared light simultaneously on the same optical axis using a CIGS image sensor 1, and a PC (Personal Computer) 5 to inspect the inspection object based on the generated visible light image and infrared light image.

The PC 5 may display the visible light image and the infrared light image in a superimposing fashion.

The CIGS camera 6 may image EL(Electro-Luminescence) light generated by flowing a current into a solar panel and the PC 5 may specify positions of defective cells included in the solar panel based on the infrared light image of the solar panel.

In addition, the PC 5 may inspect the presence of damage on the surface of the solar panel based on the visible light image of the solar panel.

Further, if the inspection object is an LSI (Large Scale Integration), the CIGS camera 6 may take an image from a side where no wiring pattern is formed.

### (Example of Circuit Configuration of Inspection System)

FIGS. 1A and 1B show a schematic circuit configuration of an inspection system according to a first embodiment. As shown in FIG. 1A, the inspection system includes the CIGS camera 6 and the PC 5. The CIGS camera 6 includes a CIGS image sensor 1, a timing generator 2, an ISP (Image Signal Processor) 3 and a USB (Universal Serial Bus) interface 4. The CIGS image sensor 1 is a sensor to receive a wide band from visible light to near-infrared light with high sensitivity, as will be described later. The timing generator 2 generates a clock signal and outputs it to the CIGS image sensor 1. The ISP 3 is a processor to process an image output from the CIGS image sensor 1 at a high speed. As shown in FIG. 1B, the ISP 3 includes a CPU (Central Processing Unit) 3a for image processing, a memory 3b to buffer an image temporarily, and an I/O (Input/Output) 3c to input/output a signal. The USB interface 4 connects the ISP 3 and the PC 5.

### (Solar Panel Inspection)

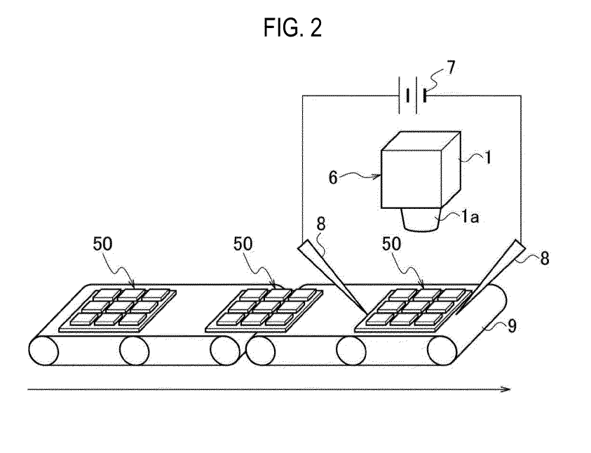

FIG. 2 is a schematic bird's-eye view showing how to inspect a plurality of solar panels 50 by the inspection system according to the first embodiment. As shown in FIG. 2, the plurality of solar panels 50 are loaded on and transferred along a belt conveyer 9. A power supply 7 is connected to terminals of one solar panel 50 via probes 8 in order to allow a current to flow into the solar panel 50. The CIGS camera 6 is placed immediately above the solar panel 50 into which the current flows, and takes images of the solar panel 50 via a micro lens 1a. Thus, a visible light image and an infrared light image of the solar panel 50 are generated and transmitted to the PC 5 (not shown in FIG. 2). The PC 5 inspects the solar panel 50 based on the transmitted visible light image and infrared light image.

### (CIGS)

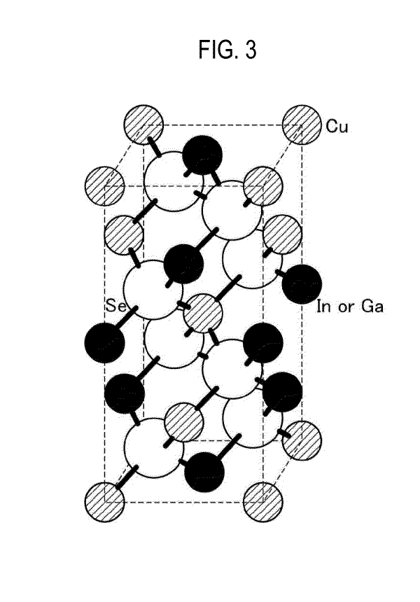

FIG. 3 shows a crystalline structure of CIGS used for the inspection system according to the first embodiment. As shown in FIG. 3, the CIGS has a chalcopyrite structure consisting of copper (Cu), indium (In), gallium (Ga) and selenium (Se). The CIGS attracts attention as the next generation solar cell thin film material and mass production of CIGS solar cells have already been started.

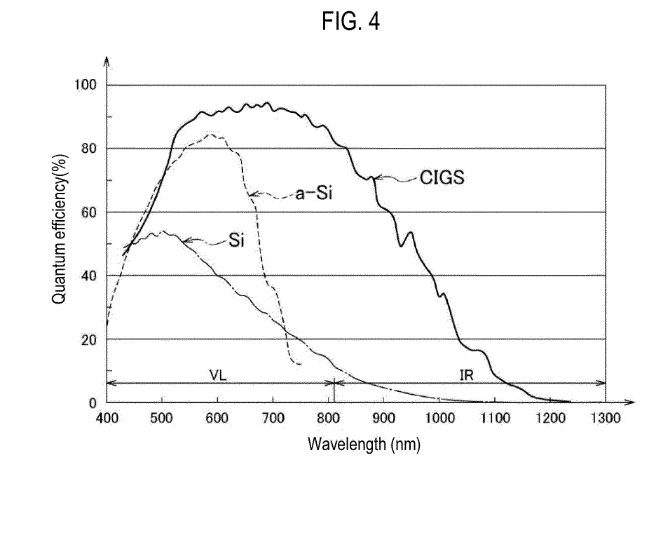

FIG. 4 is a graph showing a relationship between a wavelength and quantum efficiency of CIGS used in the inspection system according to the first embodiment. As shown in FIG. 4, the CIGS has a high quantum efficiency and a high sensitivity to near-infrared light around 1000 to 1100 nm which could not be detected by CMOS/CCD. The CIGS has a sensitivity which is about two times more than Si-PD in the visible light region and has a higher sensitivity in the near-infrared light region. The dependency of the quantum efficiency on the wavelength of the CIGS will be described in more detail later.

### (EL Light)

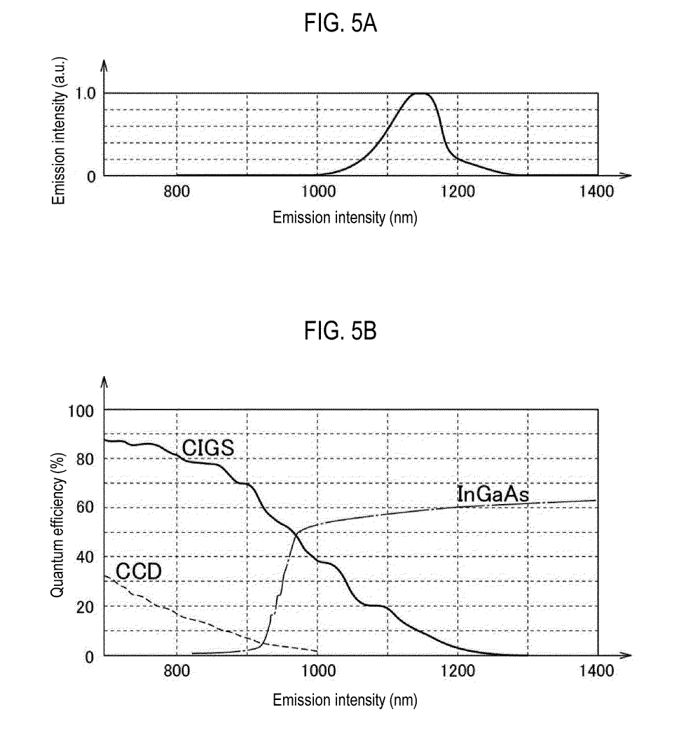

FIGS. 5A and 5B are graphs used to explain EL light generated from the solar panel 50 in the inspection system according to the first embodiment. FIG. 5A is a graph showing a relationship between emission intensity [a.u.] and wavelength [nm] of the EL light and FIG. 5B is a graph showing a relationship between quantum efficiency [%] and wavelength [nm]. As shown in FIG. 5A, the peak of EL emission is around 1150 nm, which corresponds to emission by inter-band transition. As shown in FIG. 5B, the CIGS camera 6 has a high sensitivity to near-infrared light which could not be detected by a CCD camera, and also has a high sensitivity to visible light which could not be detected by an InGaAs camera. If the solar panel 50 has any failure, no EL light is emitted. In addition, if the solar panel 50 has any leak, EL light is only emitted in the leak point. When imaging the EL emission, EL light may be emitted in a darkroom, or alternatively, a filter transmitting only EL light may be attached to the micro lens 1a of the CIGS camera 6.

### (Solar Panel)

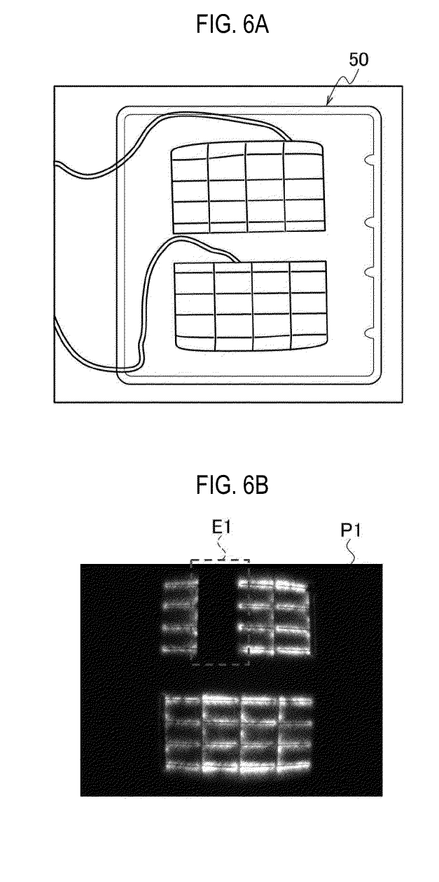

FIGS. 6A and 6B show one example of the solar panel 50 inspected by the inspection system according to the first embodiment. FIG. 6A is a schematic plane view of the solar panel 50 and FIG. 6B is an infrared light image P1 of the solar panel 50, which is generated by the CIGS camera 6. The solar panel 50 is a Si-based solar panel and is formed, for example by connecting eight cells in parallel, as shown in FIG. 6A. It is here assumed that a second one from the top left among the eight cells has a failure. Since this defective cell emits no light, a region E1 corresponding to the defective cell appears dark on the infrared light image P1, as shown in FIG. 6B. In contrast, regions of normal cells where electrodes are formed have a high current density and appear white on the infrared light image P1. Analysis on such an infrared light image P1 by the PC 5 makes it possible to discriminate between normal cells and defective cells.

### (Operation Example 1 of Inspection System)

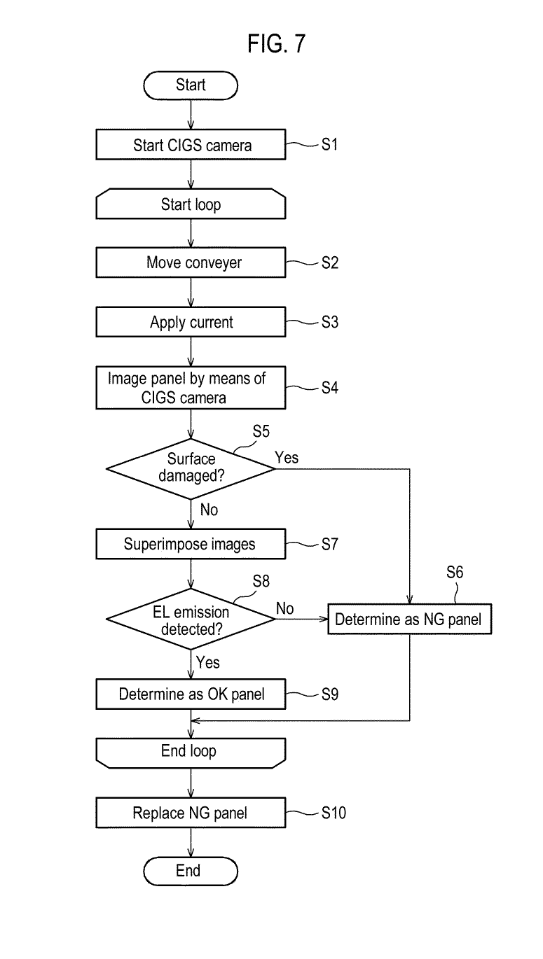

FIG. 7 is a flow chart showing an operation example of inspecting the solar panel 50 by means of the inspection system according to the first embodiment.

First, the CIGS camera 6 is started (Step S1) and a plurality of solar panels 50 are loaded on and transferred along the belt conveyer 9 (Step S2). Subsequently, a current is caused to flow into one solar panel 50 (Step S3) and its state is imaged by the CIGS camera 6 immediately from above (Step S4). A visible light image and an infrared light image of the solar panel 50, which are generated by the CIGS camera 6, are transmitted to the PC 5. Then, based on the transmitted visible light image, the PC 5 checks whether or not there is any damage to the surfaces of the solar panel 50 (Step S5). The surface checking may be automated by image processing on the PC 5, although it may be manually performed by an operator. As a result of the surface checking, if any damage is found (YES in Step S5), the corresponding solar panel 50 is determined as an NG (No Good) panel (Step S6). On the other hand, if no damage is found (NO in Step S5), the visible light image and the infrared light image of the solar panel 50 are superimposed on each other and displayed on a display of the PC 5 (Step S7) and then EL emission is checked (Step S8). The EL emission checking may be automated by image processing on the PC 5, although it may be manually performed by an operator. The superimposition of the visible light image and the infrared light image may be performed by either the PC 5 in-situ or the CIGS camera 6 in advance. A method of superimposing these images is not particularly limited but may be performed in any manner known in the art. As a result of the EL emission checking, if no EL emission for at least one cell is detected (NO in Step S8), the corresponding solar panel 50 is determined as an NG panel (Step S6). On the other hand, if EL emission for all of the cells is detected (YES in Step S8), the solar panel 50 is determined as an OK (Okay) panel (Step S9). Such a series of steps (Steps S2 to S9) is repeated for all of the solar panels 50 on the belt conveyer 9. The NG panels are unloaded from the belt conveyer 9 and are replaced with other panels (Step S10). At that time, since positions of defective cells can be specified based on the superimposed images displayed on the display, only the defective cells in the NG panels can be easily replaced with new ones.

### (Operation Example 2 of Inspection System)

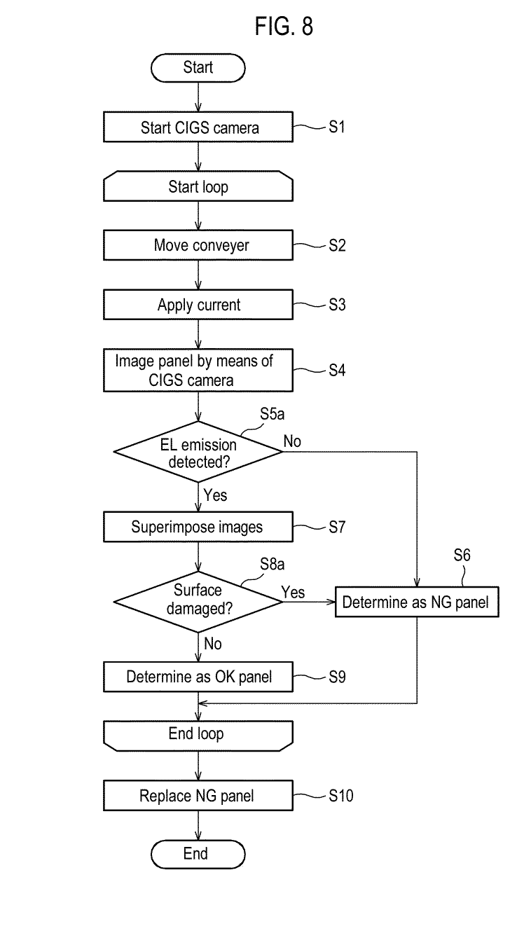

FIG. 8 is a flow chart showing another operation example of inspecting the solar panel 50 by means of the inspection system according to the first embodiment. The operation example shown in FIG. 8 is different from the operation example shown in FIG. 7 in that the surface checking and the EL emission checking are inverted in order. Specifically, as shown in FIG. 8, after the solar panel 50 is imaged by the CIGS camera 6 (Steps S1 to S4), the EL emission is checked on the basis of the infrared light image of the solar panel 50 (Step S5a). As a result of the EL emission checking, if no EL emission for at least one cell is detected (NO in Step S5a), the corresponding solar panel 50 is determined as an NG panel (Step S6). On the other hand, if EL emission for all of the cells is detected (YES in Step S5a), the visible light image and the infrared light image of the solar panel 50 are superimposed on each other and displayed on the display of the PC 5 (Step S7) and then it is checked whether or not there is any damage to the surfaces of the solar panel 50 (Step S8a). As a result of the surface checking, if any damage is found (YES in Step S8a), any corresponding solar panel 50 is determined as an NG panel (Step S6). On the other hand, if no damage is found (NO in Step S8a), the solar panel 50 is determined as an OK panel (Step S9). The subsequent operations are the same as those shown in FIG. 7.

Although it is here illustrated that the step S7 is performed between the EL emission checking (Step S5a) and the surface checking (Step S8a), the present disclosure is not limited thereto. For example, the step S7 may be performed immediately before the EL emission checking (Step S5a) or immediately before the NG panel replacement step (S 10).

### (Operation Example 3 of Inspection System)

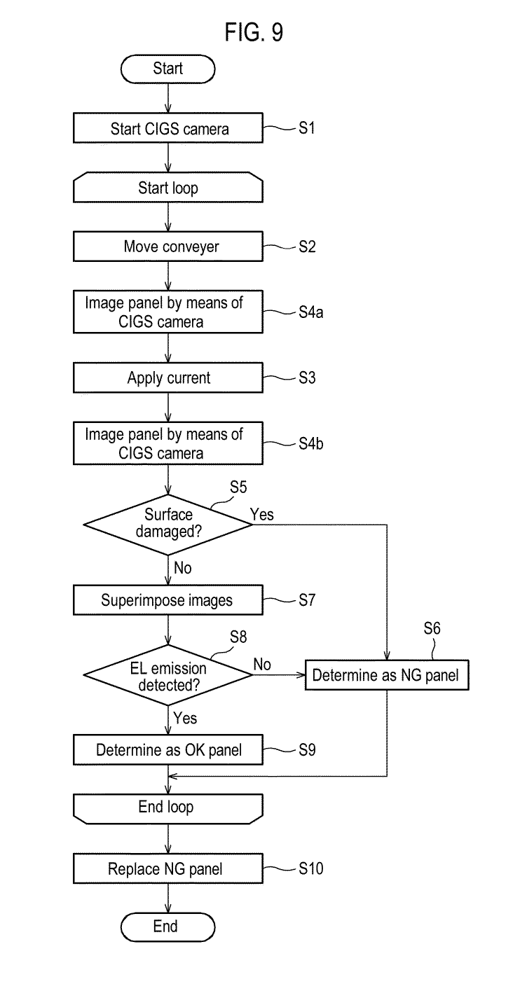

FIG. 9 is a flow chart showing still another operation example of inspecting the solar panel 50 by means of the inspection system according to the first embodiment. The operation example shown in FIG. 9 is different from the operation example shown in FIG. 7 in that the solar panel 50 is imaged before flowing a current into the solar panel 50. Specifically, as shown in FIG. 9, the solar panel 50 is loaded on and transferred along the belt conveyer 9 (Step S2) and is imaged by the CIGS camera 6 (Step S4a). Thus, a visible light image of the solar panel 50 is generated. Subsequently, a current flows into the solar panel 50 (Step S3) and is imaged by the CIGS camera 6 (Step S4b). Thus, an infrared light image of the solar panel 50 is generated. Thereafter, surface checking and EL emission checking are performed with the same procedure as the operation example shown in FIG. 7 based on the visible light image and the infrared light image (Steps S5 to S10). Although the operation example of FIG. 9 requires imaging twice, this operation example is the same as the operation examples shown in FIGS. 7 and 8 in that the visible light and the near-infrared light are imaged on the same optical axis by the CIGS camera 6.

### (LSI Inspection)

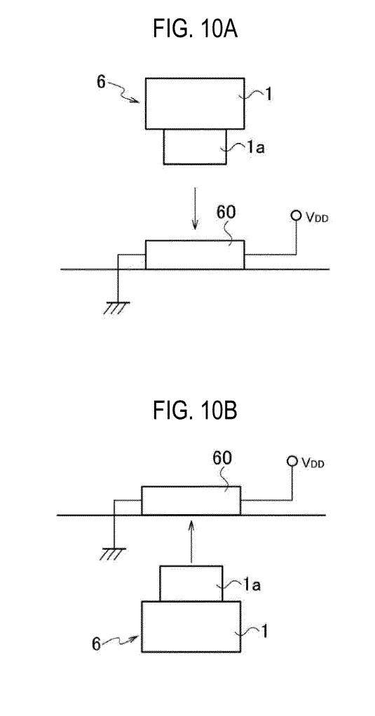

The inspection object of the inspection system according to the first embodiment is not limited to the solar panel 50. For example, as shown in FIG. 10A, a current may be flown into an LSI 60 made of silicon, which may then be imaged by the CIGS camera 6 immediately from above. If any element included in the LSI 60 is defective, the corresponding defective spot emits EL light. Therefore, like the solar panel 50, it is possible to check the goodness/badness of the LSI 60. When the LSI 60 is inspected in this manner, as shown in FIG. 10B, the CIGS camera 6 may be installed at a side where any wiring pattern of the LSI 60 is not formed. Thus, it is possible to generate a clear image even when any wiring pattern is made of material such as aluminum or the like through which light cannot penetrate.

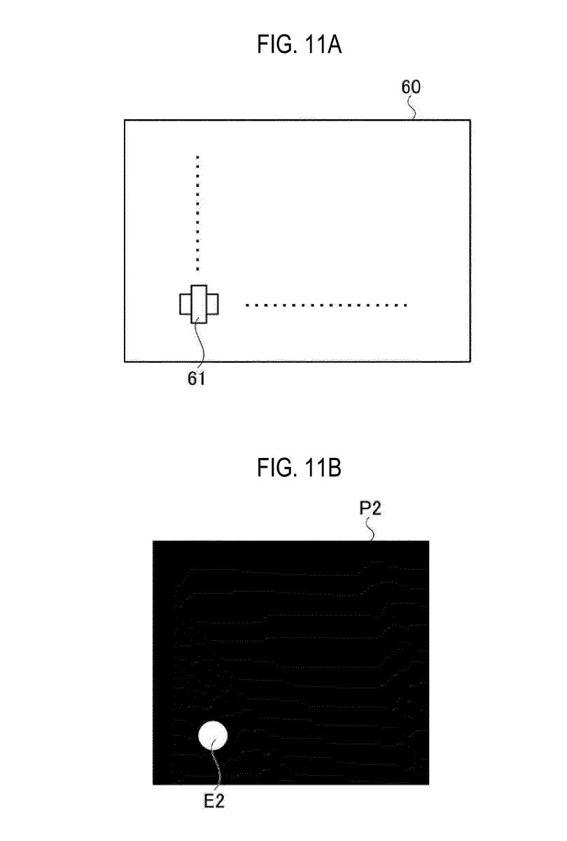

FIGS. 11A and 11B show one example of the LSI 60 inspected by the inspection system according to the first embodiment, FIG. 11A being a schematic plane view of the LSI 60 and FIG. 11B being an infrared light image P2 of the LSI 60, which is generated by the CIGS camera 6. As shown in FIG. 11A, a number of elements such as, for example, transistors 61 and the like, are mounted on the LSI 60. If one of these elements is defective, the corresponding defective spot E2 emits EL light as shown in FIG. 11B. When the infrared light image P2 is superimposed on the visible light image of the LSI 60, it is possible to specify a position of the defective element.

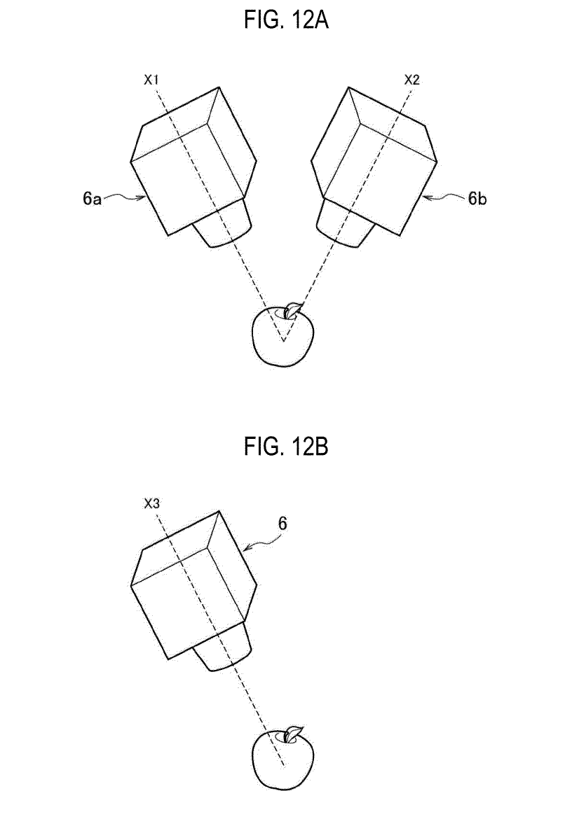

As described above, the inspection system according to the first embodiment is capable of inspecting the solar panel 50 and the like with convenience and high precision. Specifically, as shown in FIG. 12A, in the case of using two cameras, i.e., a cooled CCD camera 6a and an InGaAs camera 6b, a deviation occurs between an optical axis X1 of the cooled CCD camera 6a and an optical axis X2 of the InGaAs camera 6b, which may result in a deviation between the visible light and the infrared light image. In contrast, as shown in FIG. 12B, when using the CIGS camera 6, the visible light and the near-infrared light are simultaneously imaged on the same optical axis X3 and no deviation occurs between the visible light image and the infrared light image, thereby allowing the visible light image and the infrared light image to be superimposed. Further, since both surface checking and EL emission checking, can be performed with a single imaging, it is possible to shorten the time for which a current is flown, Furthermore, although the cooled CCD camera 6a requires long exposure, the CIGS camera 6 does not require long exposure, thereby allowing fast imaging.

### (Circuit Configuration Example of CIGS Image Sensor)

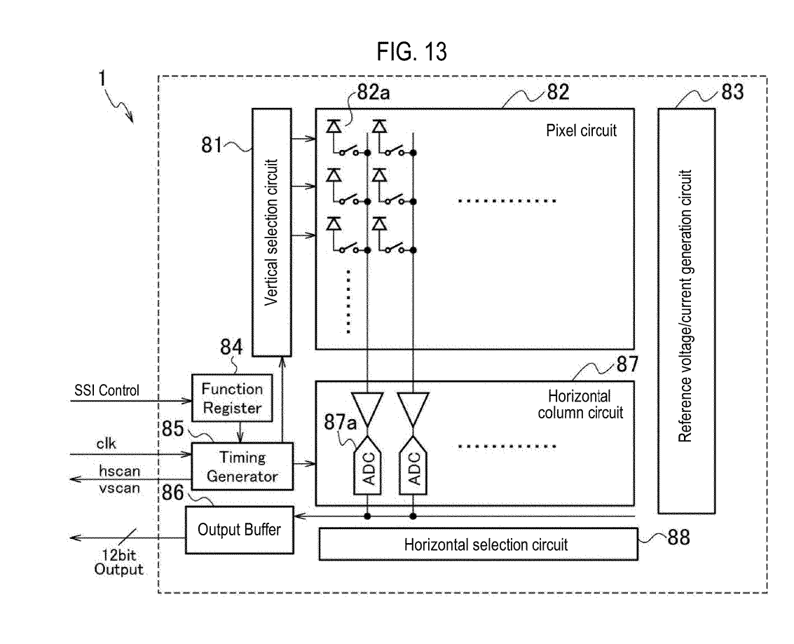

FIG. 13 shows a schematic circuit configuration of the CIGS image sensor 1 used in the inspection system according to the first embodiment. As shown in FIG. 13, the CIGS image sensor 1 is an image sensor having a pixel circuit 82 performing image-sensing on a pixel basis. Specifically, the CIGS image sensor 1 includes a pixel circuit 82 having pixels 82a arranged in the form of a matrix, a vertical selection circuit 81 to scan the pixel circuit 82 in the vertical direction, a reference voltage/current generation circuit 83 to generate a reference voltage and/or current, a function register 84 controlled from the outside via a communication protocol such as SSI (Serial Synchronous Interface) or the like, a timing generator 85 to generate a clock signal, an output buffer 86 to output 12-bit data for each pixel, a horizontal column circuit 87 having AD converters 87a arranged in a column, and a horizontal selection circuit 88 to scan the pixel circuit 82 in the horizontal direction. Charges of pixels 82a at intersections where switches of the vertical selection circuit 81 and the horizontal selection circuit 88 are switched on are transmitted to the output buffer 86. More details of the CIGS image sensor 1 will be described later.

### (Pixel Circuit)

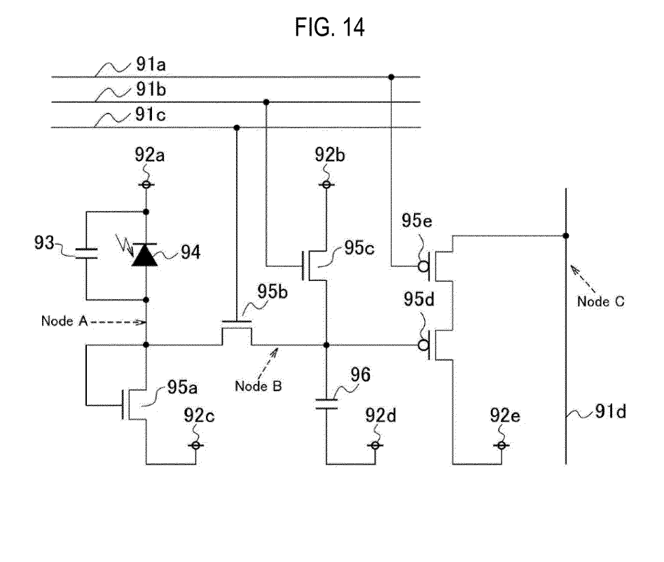

As shown in FIG. 14, the pixel circuit 82 of the CIGS image sensor 1 for use in the inspection system according to the first embodiment includes a photodiode 94 and a floating diffusion 96 and outputs a voltage V(V=Q/C) determined by an electric charge quantity Q transmitted from a parasitic capacitor 93 of the photodiode 94 to the floating diffusion 96 and a capacitance C of the floating diffusion 95.

The pixel circuit 82 further includes a transmission transistor 95b to transmit electric charges between the photodiode 94 and the floating diffusion 96, and a transmission signal line 91c connected to a gate of the transmission transistor 95b. The gate of the transmission transistor 95b may be controlled by a transmission signal input to the transmission signal line 91c.

The pixel circuit 82 further includes a reset transistor 95c to hold an electric charge of the floating diffusion 96 in an initial state, and a reset signal line 91b connected to a gate of the reset transistor 95c. The gate of the reset transistor 95c may be controlled by a reset signal input to the reset signal line 91b.

The pixel circuit 82 further includes a buffer transistor 95d to read an electric potential of a node B, an output transistor 95e to output a read signal to a vertical signal line 91d, and a selection signal line 91a connected to a gate of the output transistor 95e. The gate of the output transistor 95e may be controlled by a selection signal input to the selection signal line 91a.

### (Configuration Example of Pixel Circuit)

FIG. 14 shows a schematic circuit configuration of the pixel circuit 82 of the CIGS image sensor 1 for use in the inspection system according to the first embodiment.

As shown in FIG. 14, a cathode of the photodiode 94 is connected to a first full pixel common electrode 92a. An anode of the photodiode 94 is connected to the node A.

A first terminal of the parasitic capacitor 93 of the photodiode 94 is connected to the first full pixel common electrode 92a. A second terminal of the parasitic capacitor 93 is connected to the node A.

A gate of a transmission transistor 95a is connected to the node A. A source of the transmission transistor 95a is connected to the node A. A drain of the transmission transistor 95a is connected to a third full pixel common electrode 92c.

The gate of the transmission transistor 95b is connected to the transmission signal line 91c. A source of the transmission transistor 95b is connected to the node B. A drain of the transmission transistor 95b is connected to the node A.

A gate of the reset transistor 95c is connected to the reset signal line 91b. A source of the reset transistor 95c is connected to a second full pixel common electrode 92b. A drain of the reset transistor 95c is connected to the node B.

A gate of the buffer transistor 95d is connected to the node B. A source of the buffer transistor 95d is connected to a drain of the output transistor 95e. A drain of the buffer transistor 95d is connected to a fifth full pixel common electrode 92e.

The gate of the output transistor 95e is connected to the selection signal line 91a. A source of the output transistor 95e is connected to a node C. The drain of the output transistor 95e is connected to the source of the buffer transistor 95d.

A first terminal of the floating diffusion 96 is connected to the node B. A second terminal of the floating diffusion 96 is connected to a fourth full pixel common electrode 92d. The node C is connected to the horizontal column circuit 87.

The transmission transistors 95a and 95b exchange signals therebetween depending on the magnitude of electric potentials of the nodes A and B. That is, if the electric potential of the node A is higher than the electric potential of the node B, an electric charge is transmitted from the node A to the node B. Conversely, if the electric potential of the node B is higher than the electric potential of the node A, an electric charge is transmitted from the node B to the node A. In this manner, electric charges are exchanged between the node A and the node B, which may result in stabilization of the electric potentials of the nodes A and B which are approximately equal to each other.

The reset transistor 95c holds the electric charge of the floating diffusion 96 in an initial state and initializes the electric potential of the node B.

The buffer transistor 95d reads the electric potential of the node B. The output transistor 95e outputs this read signal to the vertical signal line 91d.

### (Operation Example of Pixel Circuit)

First, when a reset signal is input to the reset signal line 91b, the reset transistor 95c is turned on and the floating diffusion 96 is charged (reset operation). Thereafter, when a selection signal is input to the selection signal line 91a, the output transistor 95e is turned on and the buffer transistor 95d is activated to output a voltage.

Subsequently, after the reset signal is input once more and the reset operation is ended, all of the transistors 95a to 95e are turned off for a moment. Then, a photocurrent is generated from the photodiode 94 and an electric charge is stored in the parasitic capacitor 93.

Upon completion of the storage of the electric charge in the parasitic capacitor 93, the electric charge is transmitted. That is, the transmission transistor 95b is turned on and the electric charge stored in the parasitic capacitor 93 is transmitted to the floating diffusion 96. Upon completion of this transmission, the transmission transistor 95b is turned off. Then, the voltage V(V=Q/C) determined by the electric charge quantity Q transmitted from the parasitic capacitor 93 of the photodiode 94 to the floating diffusion 96 and the capacitance C of the floating diffusion 96 is output to the vertical signal line 91d.

The CIGS image sensor 1 has characteristics in that the photodiode 94 has dependency on a bias and amount of light. That is, when the photodiode 94 is illuminated with light or changed in its voltage, the capacitance of the photodiode 94 may be varied. Therefore, if an electric charge stored in this capacitance is to be output, an output voltage becomes unstable. However, according to the above operation, since the voltage V determined by the electric charge quantity Q transmitted from the parasitic capacitor 93 of the photodiode 94 to the floating diffusion 96 and the capacitance C of the floating diffusion 96 is output, it becomes possible to obtain a stable output voltage.

### (Waveform Example of Pixel Circuit)

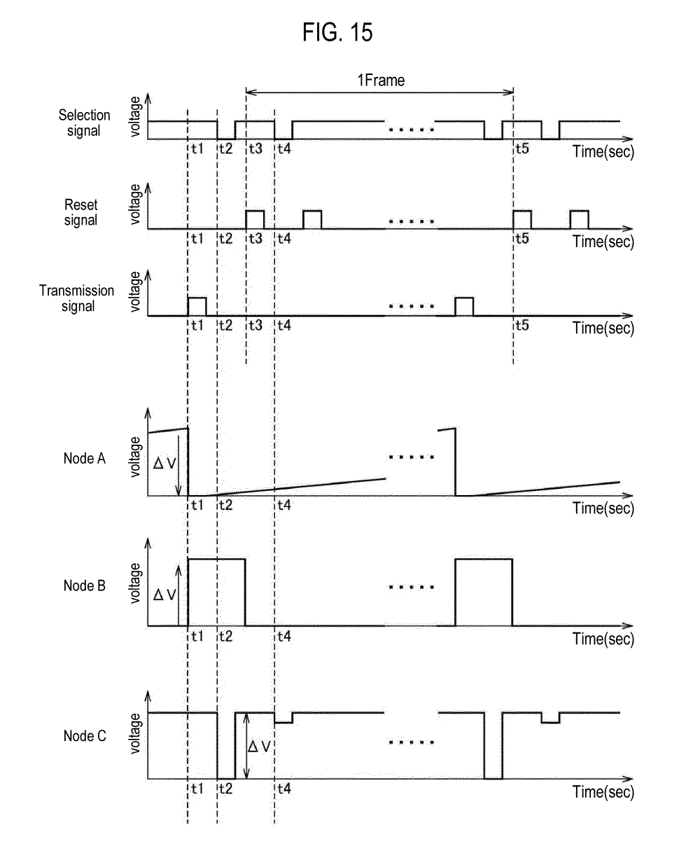

FIG. 15 is a timing chart showing example waveforms representing temporal changes of voltages in the pixel circuit 82 of the CIGS image sensor 1 for use in the inspection system according to the first embodiment of the present disclosure. The upper three waveforms in FIG. 15 show a selection signal, a reset signal and a transmission signal, respectively.

Electric charges are transmitted at time t1, the charge transmission is read at time t2, pixels are reset at time t3, and the reset pixels are read at time t4.

The lower three waveforms in FIG. 15 are examples of waveforms at the nodes A, B and C, respectively,

Signal charges are transmitted from the node A to the node B at time t1, the transmitted charges are output from the node C at time t2, and reset charges are output from the node C at time t4.

### Comparative Example

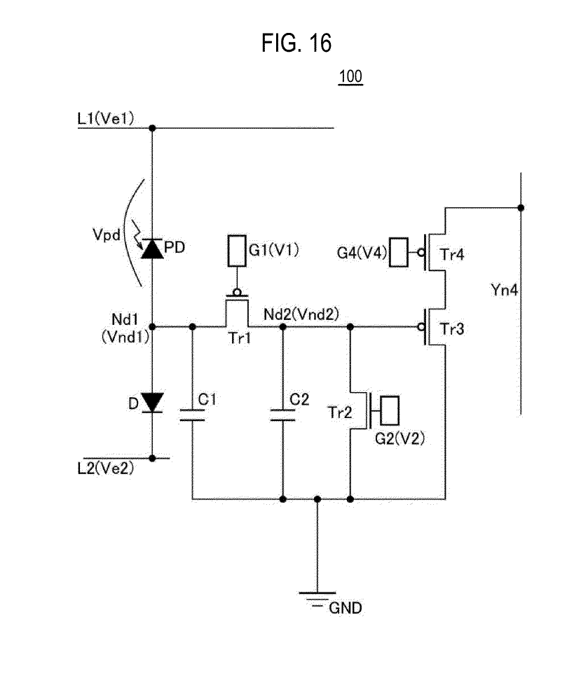

FIG. 16 shows a schematic circuit configuration of a photo-electric conversion circuit 100 according to a comparative example.

As shown in FIG. 16, a photo-electric conversion element (photodiode) PD and a diode D are connected in the opposite direction and in series between a first control line L1 and a second control line L2.

When the diode element D is biased in the forward direction, a predetermined voltage is applied between a cathode and an anode of the photo-electric conversion element PD. Accordingly, a predetermined voltage Vpd is applied to a plurality of photo-electric conversion elements PD and the dependency of the plurality of photo-electric conversion elements PD on a bias is excluded.

One difference of the photo-electric conversion circuit 100 from the pixel circuit 82 is how to apply a signal to a control electrode G1 of a transistor Tr1. That is, in the photo-electric conversion circuit 100, a predetermined bias (transmission) voltage V1 is applied to the control electrode G1 of the transistor Tr1. In contrast, in the pixel circuit 82, the gate of the transmission transistor 95b is turned on and off with a pulse.

### Second Embodiment

A second embodiment will now be described with stress placed on differences from the first embodiment.

### (Heat Detection)

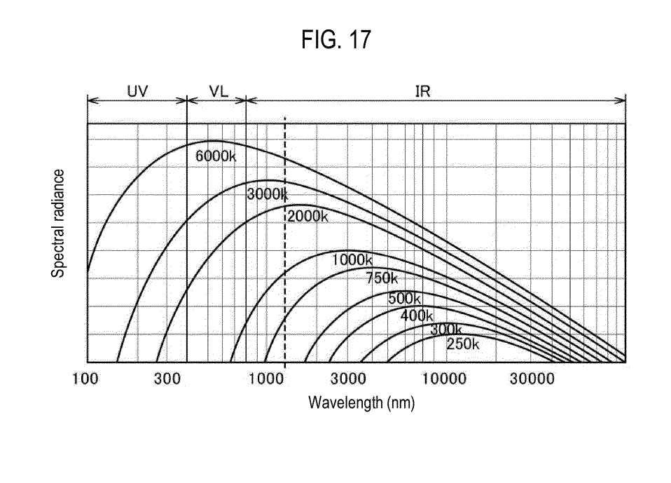

FIG. 17 is a graph used to explain infrared light generated from an inspection object in an inspection system according to the second embodiment of the present disclosure. In the graph, the vertical axis represents a spectral radiance and the horizontal axis represents a wavelength [nm]. As shown in FIG. 17, an object emits an electromagnetic wave having a wavelength and intensity depending on the temperature of the object (black body radiation). For example, infrared light having a wavelength of about 1200 nm or less is emitted if the temperature of the object exceeds about 350 degrees C. or more, and infrared light having a wavelength of about 1300 nm or less is emitted if the temperature of the object exceeds about 300 degrees C. or more. Therefore, in the inspection system according to the second embodiment, the CIGS camera 6 is used to image a heat source and it is checked whether or not heat is generated, based on the imaged heat source.

More specifically, the CIGS camera 6 images infrared light generated at a hot spot of a specific temperature or higher and the PC 5 specifies a position of heat generation of the inspection object based on the infrared light image of the inspection object. If heat is generated from the inspection object, the PC 5 may output a warning to inform of the danger.

### (Soldering Iron)

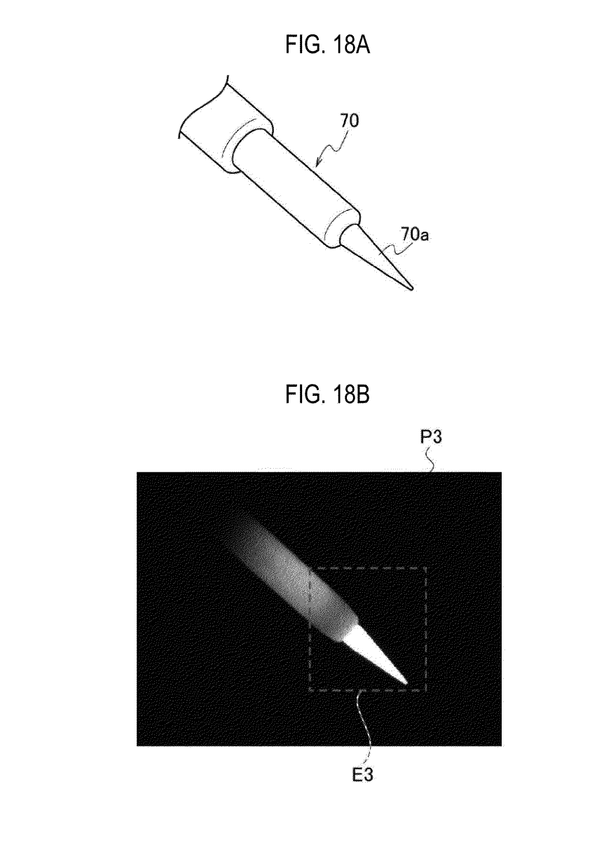

FIGS. 18A and 18B show one example of an inspection object inspected by the inspection system according to the second embodiment, FIG. 18A being a schematic bird's eyes view of a soldering iron 70 and FIG. 18B being an infrared light image P3 of the soldering iron 70, which is generated by the CIGS camera 6. As shown in FIG. 18A, the soldering iron 70 includes a soldering tip 70a made of, for example, copper. When the soldering tip 70a is heated to, for example, about 350 degrees C., a region E3 corresponding to the soldering tip 70a emits light in white on the infrared light image P3, as shown in FIG. 18B. Since this emission becomes stronger with higher temperature, it is possible to find a hot spot of a specific temperature or higher through analysis on the infrared light image P3.

### (Operation Example of Inspection System)

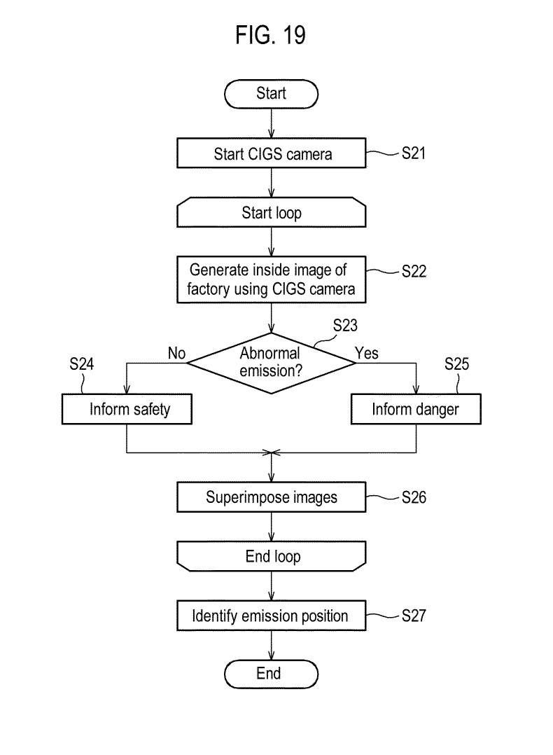

FIG. 19 is a flow chart showing an operation example of detecting heat by means of the inspection system according to the second embodiment. It is here assumed that the CIGS camera 6 is installed as a surveillance camera in a factory where a device including a driving unit such as a motor or the like is manufactured.

First, the CIGS camera 6 is started (Step S21). Thus, based on a visible light image generated by the CIGS camera 6, the inside of the factory is monitored (Step S22). Further, based on an infrared light image generated by the CIGS camera 6, it is determined whether or not there is abnormal emission (Step S23). Here, if none of the motors in the factory emits heat (NO in Step S23), it is determined that there is no abnormal emission (Step S24). On the other hand, if any of the motors in the factory emits heat (YES in Step S23), it is determined that there is abnormal emission (Step S25). How to inform of a safe condition or a dangerous condition is not particularly limited but, for example, the PC 5 may be used to display a warning message or sound an alarm. The visible light image and the infrared light image of the inside of the factory may be superimposed and displayed on a display of the PC 5 (Step S26). In this way, if there is abnormal light emission, it is possible to identify the heating position (Step S27).

As described above, in the inspection system according to the second embodiment, the CIGS camera 6 is used to image the source of heat. In such heat detection, since the visible light and the near-infrared light are imaged simultaneously on the same optical axis, no deviation occurs between the visible light image and the infrared light image, which may result in the same effects as the first embodiment.

### [Example of CIGS Image Sensor]

### (Planar Pattern Configuration)

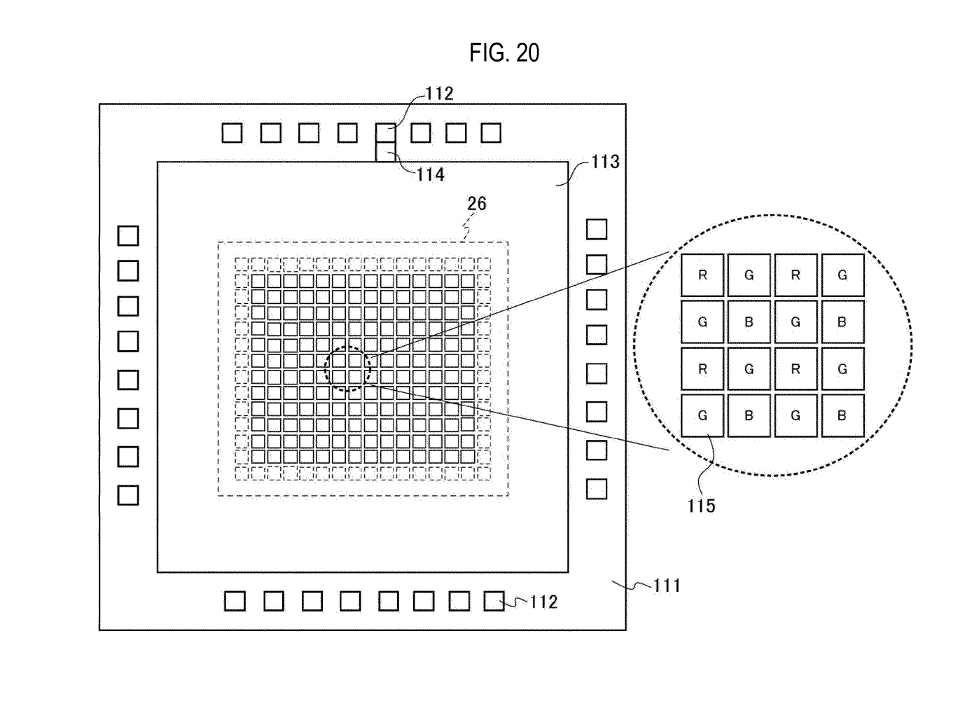

FIG. 20 shows a schematic overall planar pattern configuration of a color solid state imaging device which can be applied to the CIGS image sensor 1 for use in the inspection system according to the first or second embodiment. As shown in FIG. 20, the color solid state imaging device may include a package substrate 111, a plurality of bonding pads 112 arranged in the periphery of the package substrate 111, and an aluminum electrode layer 113 which is connected to one of the bonding pads 112 by means of a bonding pad connector 114. The aluminum electrode layer 113 is also connected to a transparent electrode layer 26 disposed on pixels 115 of the color solid state imaging device in the periphery of the color solid state imaging device. That is, the aluminum electrode layer 113 covers a periphery portion of the transparent electrode layer 26 and is connected to one bonding pad 112 by means of the boding pad connector 114. As indicated by an enlarged dotted circle in FIG. 20, the pixels 115 are arranged in the form of a fine matrix. In the example of FIG. 20, each pixel 115 has R (Red), G (Green) and B (Blue) visible light filters arranged on the transparent electrode layer 26 with predetermined regularity. Although the arrangement of the RGB visible light filters in a Bayer pattern is illustrated in the example of FIG. 20, infrared light filters may be arranged adjacent to the visible light filters.

### (Color Solid State Imaging Device)

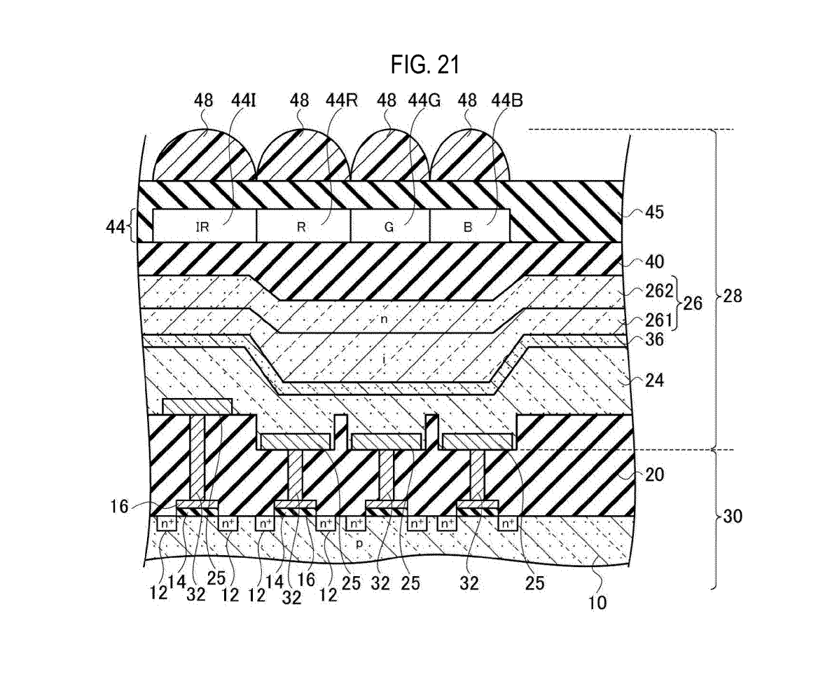

As shown in FIG. 21, a schematic sectional structure of the color solid state imaging device which can be applied to the CIGS image sensor 1 for use in the inspection system according to the first or second embodiment includes a circuit part 30 formed on a semiconductor substrate 10 and a photo-electric conversion part 28 disposed on the circuit part 30.

As shown in FIG. 21, the photo-electric conversion part 28 includes a lower electrode layer 25 disposed on the circuit part 30, a chalcopyrite-structured compound semiconductor thin film 24 disposed on the lower electrode layer 25, a buffer layer 36 disposed on the compound semiconductor thin film 24, a transparent electrode layer 26 disposed on the buffer layer 36, and a filter layer 44 disposed on the transparent electrode layer 26.

The lower electrode layer 25, the compound semiconductor thin film 24, the buffer layer 36 and the transparent electrode layer 26 are sequentially stacked on the circuit part 30 and, a portion of the compound semiconductor thin film 24 below visible light filters 44R, 44G and 44B is thinned to absorb only the visible light.

In addition, as shown in FIG. 21, an infrared light filter 44I may be disposed on the transparent electrode layer 26 and the portion of the compound semiconductor thin film 24 below the visible light filters 44R, 44G and 44B may be made thinner than a portion of the compound semiconductor thin film 24 below the infrared light filter 44I, so that the portion of the compound semiconductor thin film 24 below the infrared light filter 44I can absorb only near-infrared light. That is, the color solid state imaging device which can be applied to the CIGS image sensor 1 for use in the inspection system according to the first or second embodiment can be configured to have a sensitivity in not only a visible light region but also a near-infrared light region.

The buffer layer 36 disposed on the compound semiconductor thin film 24 is integrally formed on the entire surface of the semiconductor substrate 10. The transparent electrode layer 26 is formed on the entire surface of the semiconductor substrate 10 and is electrically connected thereto.

An interlayer insulating film 40 is disposed on the transparent electrode layer 26 and the filter layer 44 (filters 44R, 44G, 44B and 44I) is disposed on a planarized surface of the interlayer insulating film 40. A clear filter 45 formed of a passivation film or the like is disposed on the filter layer 44 and micro lenses 48 may be disposed on the clear filter 45 to correspond to respective R, G, B and IR pixels.

In the color solid state imaging device which can be applied to the CIGS image sensor 1 for use in the inspection system according to the first or second embodiment, multiplication of electric charges generated by photo-electric conversion may be made by impact ionization within the chalcopyrite-structured compound semiconductor thin film 24, for example by applying a reverse bias voltage between the transparent electrode layer 26 and the lower electrode layer 25.

The circuit part 30 includes transistors, having gates connected to the lower electrode layer 25.

In the color solid state imaging device shown in FIG. 21, the chalcopyrite-structured compound semiconductor thin film 24 is made of Cu(In_{X}, Ga_{1-X})Se₂ (0≦X≦1).

The lower electrode layer 25 may be made of, for example, molybdenum (Mo), niobium (Nb), tantalum (Ta), tungsten (W) or the like.

The buffer layer 36 may be made of, for example, CdS, ZnS, ZnO, ZnMgO, ZnSe, In₂S₃ or the like.

The transparent electrode layer 26 includes a semi-insulating layer (iZnO layer) 2.61 formed of a non-doped ZnO film and disposed on the compound semiconductor thin film 24, and an upper electrode layer (nZnO layer) 2.62 formed of an type ZnO film and disposed on the semi-insulating layer 261.

In addition, a high-resistance layer (i type CIGS layer) (not shown) may be formed on the surface of the compound semiconductor thin film 24.

The circuit part 30 may include, for example, CMOS field effect transistors (FETs).

In FIG. 21, the circuit part 30 has n channel MOS (Metal Oxide Semiconductor) transistors constituting a part of CMOS, and includes the semiconductor substrate 10, source/drain diffusion layers 12 formed in the semiconductor substrate 10, gate insulating films 14 disposed on the semiconductor substrate 10 between the source/drain diffusion layers 12, gate electrodes 16 disposed on the gate insulating films 14, and via electrodes 32 disposed on the gate electrodes 16.

Both of the gate electrodes 16 and the via electrodes 32 are formed in an interlayer insulating film 20.

In the color solid state imaging device shown in FIG. 21, the gate electrodes 16 of the n channel MOS transistors constituting a part of CMOS and the photo-electric conversion part 28 are electrically connected by the via electrode 32 disposed on the gate electrodes 16.

Since an anode of the photodiode constituting the photo-electric conversion part 28 is connected to the gate electrodes 16 of the n channel MOS transistors, optical information detected by the photodiode is amplified by the n channel MOS transistors.

In addition, the circuit part 30 may be formed, for example by CMOS thin film transistors disposed on a thin film formed on a glass substrate.

### (Modification)

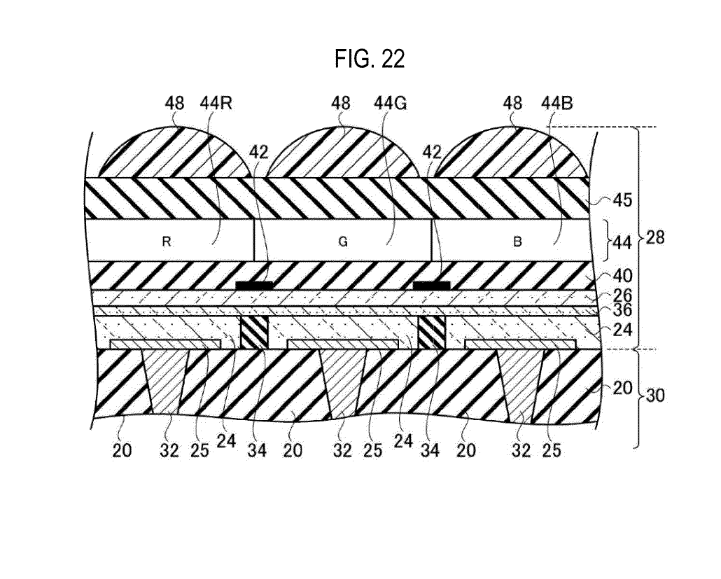

FIG. 22 shows a schematic sectional structure of a modification of the color solid state imaging device which can be applied to the CIGS image sensor 1 for use in the inspection system according to the first or second embodiment. FIG. 22 is an enlarged view of an RGB pixel region having thinned compound semiconductor thin films 24. Although not shown in FIG. 22, an IR pixel having a relatively thick compound semiconductor thin film 24 therebelow is disposed adjacent to the RGB pixel region, like FIG. 21.

As can be seen from FIG. 22, the compound semiconductor thin films 24 disposed on the lower electrode layers 25 are separated from each other by isolation regions 34 between adjacent pixels. The isolation regions 34 may be formed by the interlayer insulating film 20. In addition, light shielding layers 42 having substantially the same width as the isolation regions 34 and made of, for example, aluminum (Al) or the like are disposed in sites on the transparent electrode layer 26 corresponding to the isolation regions 34.

The width of the compound semiconductor thin films 24 may be equal to the width of the lower electrode layers 25, or alternatively, as shown in FIG. 22, the width of the compound semiconductor thin films 24 may be set to be larger than the width of the lower electrode layers 25.

The other configurations are the same as those in the color solid state imaging device which can be applied to the CIGS image sensor 1 for use in the inspection system according to the first or second embodiment and, therefore, explanation of which is not repeated.

### (Filter)

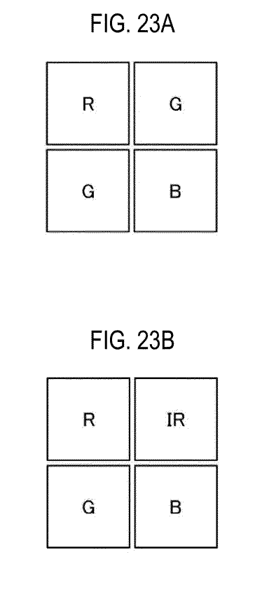

As shown in FIG. 23A, an array of color filters applied to the color solid state imaging device which can be applied to the CIGS image sensor 1 for use in the inspection system according to the first or second embodiment has a Bayer pattern including one R filter, one B filter and two G filters. Alternatively, as shown in FIG. 23B, an IR filter may be disposed in addition to one R filter, one G filter and one B filter. An array of filters is not limited to the square lattice arrays shown in FIGS. 23A and 23B but may be, for example, a honeycomb array. The color filters may be made of, for example, pigment-based color resists, transparent resists formed using a nanoimprint technique, gelatin films or the like.

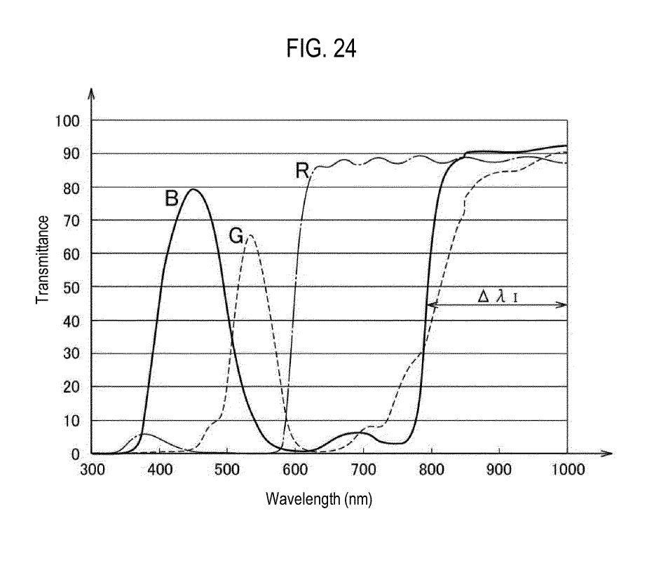

FIG. 24 shows transmission characteristics of color filters applied to the color solid state imaging device which can be applied to the CIGS image sensor 1 for use in the inspection system according to the first or second embodiment. As can be seen from FIG. 24, all of the RGB visible light filters show specific transmittances in a near-infrared light wavelength range represented by αλ₁ other than an RGB wavelength range. Therefore, as will be described later, in the color solid state imaging device which can be applied to the CIGS image sensor 1 for use in the inspection system according to the first or second embodiment, the sensitivity to infrared light and near-infrared light is blocked by controlling thickness and/or band gap energy Eg of the compound semiconductor thin film 24.

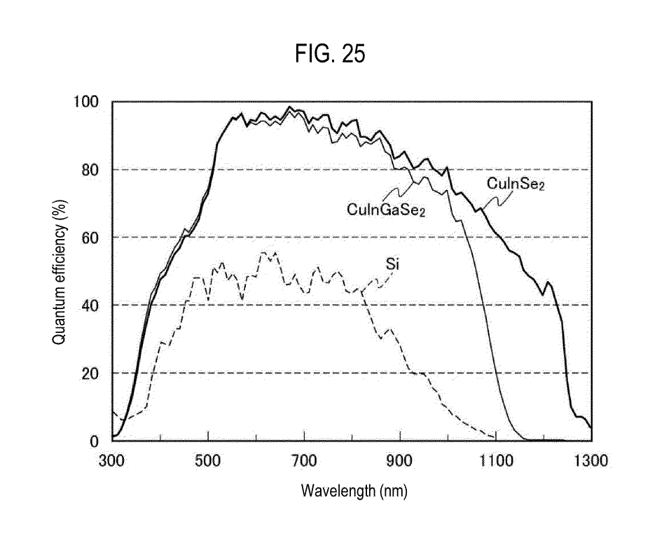

FIG. 25 shows the dependency of quantum efficiency on wavelength for a CIGS film applied to the color solid state imaging device which can be applied to the CIGS image sensor 1 for use in the inspection system according to the first or second embodiment. Specifically, the chalcopyrite-structured compound semiconductor thin film (Cu(In_{X}, Ga_{1-X})Se₂ (0≦X≦1)) 24 acting as a light absorbing layer shows photo-electric conversion characteristics of high quantum efficiency in a wide wavelength range from visible light to near-infrared light. The quantum efficiency for the thin film 24 is more than double, as compared to photo-electric conversion characteristics for silicon (Si). In particular, a mixed crystal of CuInSe2 and CuGaSe2 can provide a high quantum efficiency of about 90% or higher in the visible light region.

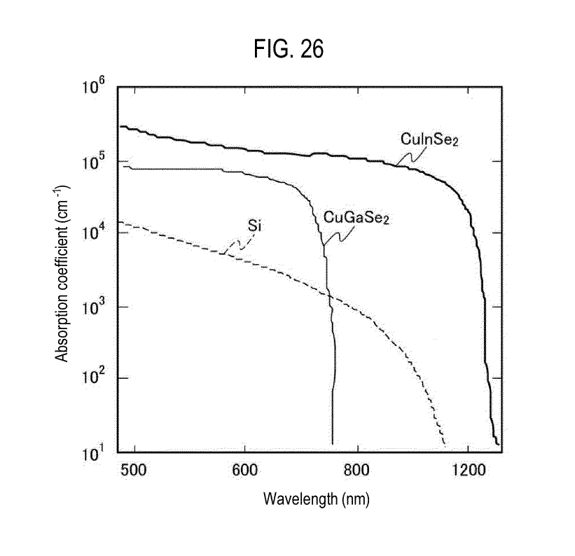

FIG. 26 shows light absorption characteristics of a CIGS film applied to the color solid state imaging device which can be applied to the CIGS image sensor 1 for use in the inspection system according to the first or second embodiment. Specifically, the chalcopyrite-structured compound semiconductor thin film (Cu(In_{X}, Ga_{1-X})Se₂ (0≦X≦1) 24 acting as a light absorbing layer has a high absorption capability in a wide wavelength range from visible light to near-infrared light.

For example, an absorption coefficient for the thin film 24 is about 100 times as high as that for silicon (Si).

### (Dependency of CIGS Film on Film Thickness)

In the color solid state imaging device which can be applied to the CIGS image sensor 1 for use in the inspection system according to the first or second embodiment, it is possible to control a quantum efficiency by controlling the thickness of the chalcopyrite-structured compound semiconductor thin film (Cu(Inₓ, Ga₁₋ₓ)Se₂ (0≦X≦1)) 24 acting as a light absorbing layer.

In the color solid state imaging device which can be applied to the CIGS image sensor 1 for use in the inspection system according to the first or second embodiment, the chalcopyrite-structured compound semiconductor thin film 24 can have a quantum efficiency, particularly in the visible light region, by controlling the thickness of the chalcopyrite-structured compound semiconductor thin film 24 acting as a light absorbing layer. Therefore, in the color solid state imaging device which can be applied to the CIGS image sensor 1 for use in the inspection system according to the first or second embodiment, as shown in FIG. 21, it is possible to absorb only incident light in the RGB wavelength range by thinning the compound semiconductor thin film 24 and arranging the visible light filters 44R, 44G and 44B on the transparent electrode layer 26 via the interlayer insulating film 40.

In addition, in the color solid state imaging device which can be applied to the CIGS image sensor 1 for use in the inspection system according to the first or second embodiment, the chalcopyrite-structured compound semiconductor thin film 24 can have a quantum efficiency, particularly in the infrared or near-infrared light region, by setting the chalcopyrite-structured compound semiconductor thin film 24 acting as a light absorbing layer to a predetermined thickness. Therefore, as shown in FIG. 21, it is possible to absorb only incident light in the infrared or near-infrared light wavelength range by setting the compound semiconductor thin film 24 to the predetermined thickness and arranging the infrared light filter 44I on the transparent electrode layer 26 via the interlayer insulating film 40.

As apparent from the above, in the color solid state imaging device which can be applied to the CIGS image sensor 1 for use in the inspection system according to the first or second embodiment, since a quantum efficiency for the wavelength ranges of all of the visible light, the infrared light and the near-infrared light can be provided, it is possible to provide a solid state imaging device for both visible light and infrared light or near-infrared light. For example, the solid state imaging device may be used in a security camera sensing visible light in the daytime and near-infrared light at night.

### (Band Gap Energy Control of CIGS Film)

In the color solid state imaging device which can be applied to the CIGS image sensor 1 for use in the inspection system according to the first or second embodiment, it is possible to control a quantum efficiency by controlling a value of band gap energy of the chalcopyrite-structured compound semiconductor thin film (Cu(In_{X}, Ga_{1-X})Se₂ (0≦X≦1) 24 acting as a light absorbing layer. Specifically, since a wavelength range where a predetermined quantum efficiency is obtained can be controlled by controlling band gap energy Eg of the compound semiconductor thin film 24, near-infrared light can be prevented from being absorbed, for example by setting the wavelength range to a visible light wavelength range.

Since the band gap energy Eg is represented by an equation of hc/λ, (where, h is the Plank constant, c is the speed of light and λ, is a wavelength of light to be absorbed), it is possible to narrow the wavelength range, for example by increasing a value of the band gap energy Eg.

In the color solid state imaging device which can be applied to the CIGS image sensor 1 for use in the inspection system according to the first or second embodiment, it is possible to realize a configuration in which a pixel region where visible light filters are arranged absorbs only visible light and a pixel region where a near-infrared light filter is arranged absorbs only near-infrared light by controlling both the thickness and band gap energy Eg of the compound semiconductor thin film 24.

### (First Manufacturing Method)

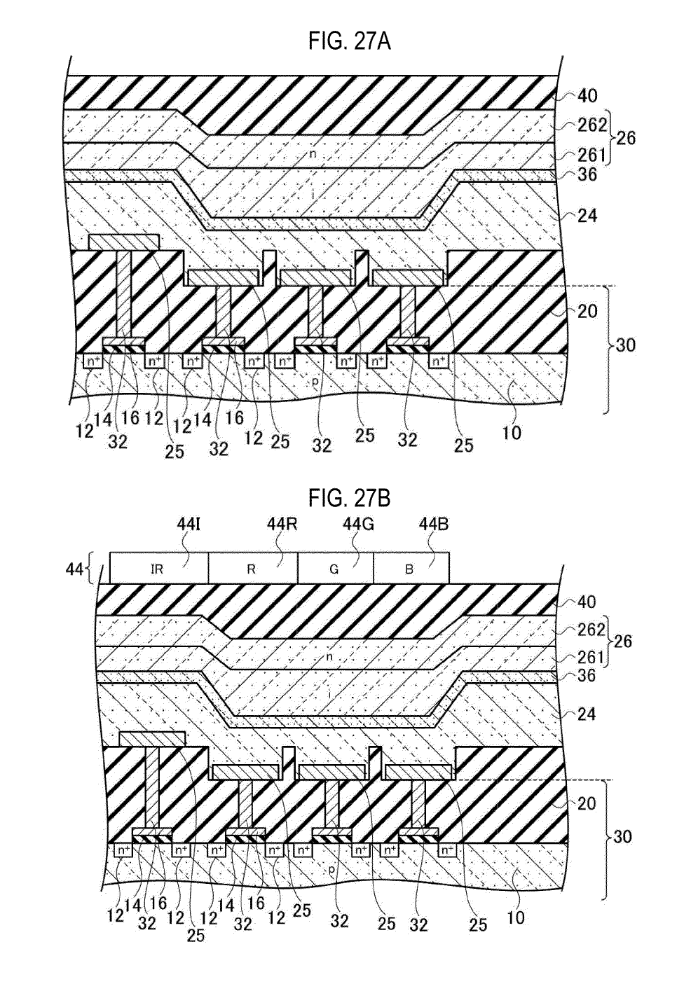

FIGS. 27A and 27B show a first method for manufacturing the color solid state imaging device which can be applied to the CIGS image sensor 1 for use in the inspection system according to the first or second embodiment. In the first manufacturing method, a stepped structure is formed in advance in the interlayer insulating film 20 in order to form a stepped structure in the compound semiconductor thin film 24.

Specifically, as shown in FIG. 27A, the interlayer insulating film 40 is planarized. For example, a CMP (Chemical Mechanical Polishing) technique may be applied to this planarization process.

Next, as shown in FIG. 27B, the filter layer 44 is formed on the planarized interlayer insulating film 40. The visible light filters 44R, 44G and 44B are disposed on a portion of the interlayer insulating film 40 corresponding to a pixel region for detection of RGB visible light and the infrared light filter 44I is disposed on a portion of the interlayer insulating film 40 corresponding to a pixel region for detection of infrared light.

Next, as shown in FIG. 21, after forming the clear filter 45 formed of, for example, a passivation film on the filter layer 44 and the interlayer insulating film 40, the micro lenses 48 for condensation of optical information are disposed on the clear filter 45 above the visible light filters 44R, 44G and 44B and the infrared light filter 44I, respectively, thereby completing the color solid state imaging device which can be applied to the CIGS image sensor 1 for use in the inspection system according to the first or second embodiment.

### (Second Manufacturing Method)

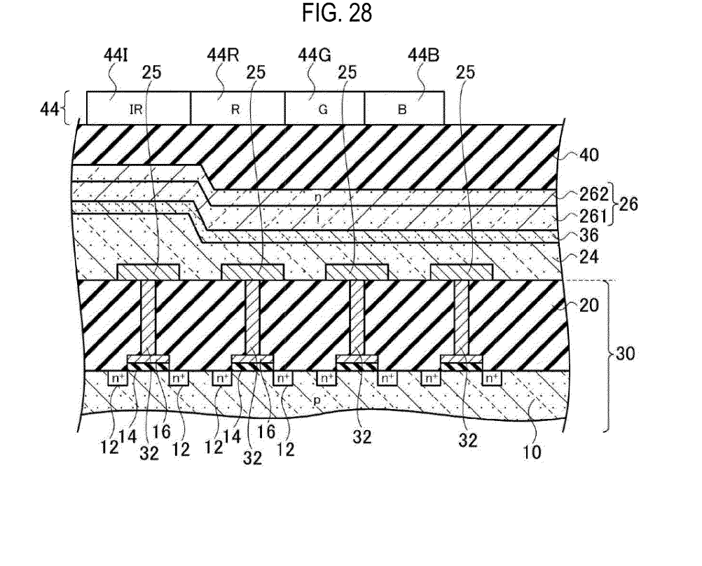

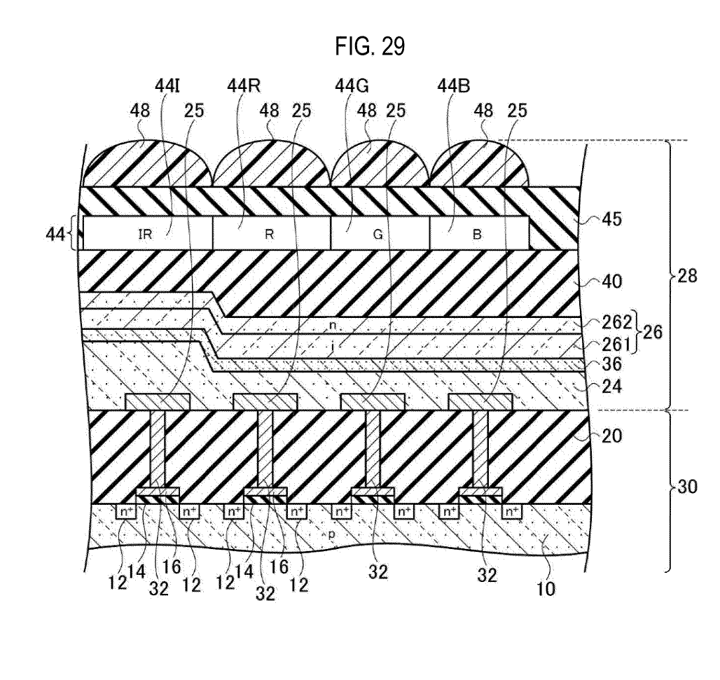

FIGS. 28 and 29 show a second method for manufacturing the color solid state imaging device which can be applied to the CIGS image sensor 1 for use in the inspection system according to the first or second embodiment. In the second manufacturing method, a stepped structure is directly formed in the compound semiconductor thin film 24.

Specifically, as shown in FIG. 28, the filter layer 44 is formed on the planarized interlayer insulating film 40. The visible light filters 44R, 44G and 44B are disposed on a portion of the interlayer insulating film 40 corresponding to a pixel region for detection of RGB visible light and the infrared light filter 44I is disposed on a portion of the interlayer insulating film 40 corresponding to a pixel region for detection of infrared light.

Next, as shown in FIG. 29, after forming the clear filter 45 formed of, for example, a passivation film on the filter layer 44 and the interlayer insulating film 40, the micro lenses 48 for condensation of optical information are disposed on the clear filter 45 above the visible light filters 44R, 44G and 44B and the infrared light filter 44I, respectively, thereby completing the color solid state imaging device which can be applied to the CIGS image sensor 1 for use in the inspection system according to the first or second embodiment.

### (Compound Semiconductor Thin Film Forming Process)

The compound semiconductor thin film 24 acting as a light absorbing layer may be formed on the semiconductor substrate 10 or a glass substrate having the circuit part 30 formed thereon by means of a vacuum deposition method called PVD (Physical Vapor Deposition) method, a sputtering method or an MBE (Molecular Beam Epitaxy) method. As used herein, the term “PVD method” refers to a method for forming a film by depositing a raw material evaporated in vacuum.

In the case of using the vacuum deposition method, ingredients (Cu, In, Ga, Se and S) of the compound as a source of deposition are deposited on the substrate having the circuit part 30 formed thereon.

In the case of using the sputtering method, a chalcopyrite compound is used as a target or ingredients of the compound are used as separate targets.

In the case of forming the compound semiconductor thin film 24 on the glass substrate having the circuit part 30 formed thereon, since the glass substrate is heated to a high temperature, a composition difference due to separation of chalcogenide elements may occur. In this case, Se or S may be supplemented by performing heat treatment for the formed thin film at a temperature of 400 to 600 degrees C. for one to several hours under a Se or S vapor atmosphere (selenization process or sulfurization process).

A method of manufacturing the compound semiconductor thin film 24 applied to the color solid state imaging device which can be applied to the CIGS image sensor 1 for use in the inspection system according to the first or second embodiment includes a first step (period 1a) of maintaining a substrate temperature at a first temperature T1 and maintaining a III group element excessive state where a composition ratio of (Cu/In+Ga)) is zero, a second step (period 2a) of maintaining the substrate temperature at a second temperature T2 higher than the first temperature T1 and transiting to a Cu element excessive state where the (Cu/In +Ga)) composition ratio is 1.0 or more, and a third step (period 2a) of transiting from the Cu element excessive state where the (Cu/In+Ga)) composition ratio is 1.0 or more to a III group element excessive state where the (Cu/In+Ga)) composition ratio is 1.0 or less. The third step forms the chalcopyrite-structured compound semiconductor thin film 24 by providing a first period (period 3a) during which the substrate temperature is maintained at the second temperature T2 and a second period (period 3b) during which the substrate temperature decreases from the second temperature T2 to a third temperature T3 lower than the first temperature T1.

The third temperature T3 is, for example, equal to or higher than about 300 degrees C. and equal to or lower than about 400 degrees C.

The second temperature is, for example, equal to or lower than about 550 degrees C.

In the third step, for example, the composition ratio of (Cu/In+Ga)) at the end of the first period (period 3a) may be set to a range of, for example, about 0.5 to 1.3 and the composition ratio of (Cu/In+Ga)) at the end of the second period (period 3b) may be set to a range of, for example, 1.0 or below.

In the method of manufacturing the compound semiconductor thin film 24 applied to the color solid state imaging device which can be applied to the CIGS image sensor 1 for use in the inspection system according to the first or second embodiment, the third step is divided into two steps, i.e., the period 3a and the period 3b. The period 3a is a high temperature process step of the temperature T2, while the period 3b is a low temperature process step of the temperature T3. Accordingly, an i type CIGS layer (not shown) is actively formed on the surface of the compound semiconductor thin film 24 during the period 3b. The substrate temperature during the period 3b is 300 degrees C. to 400 degrees C., for example, about 300 degrees C.

As described above, instead of depositing the constituent elements at once, the deposition is performed by the three steps to control a distribution of the constituent elements in the film to some extent. A beam flux of In and Ga elements is used to control the band gap of the compound semiconductor thin film 24. In addition, a Cu/III group (In+Ga) ratio can be used to control a Cu concentration in the compound semiconductor thin film 24. It is relatively easy to set the Cu/III group (In+Ga) ratio. It is also easy to control the film thickness. A constant amount of Se is supplied during the first to third steps.

Since setting the Cu/III group (In+Ga) ratio is relatively easy, in the third step, the Cu/III group (In+Ga) ratio may be lowered to allow the i type CIGS layer to be easily formed on the surface of the compound semiconductor thin film 24 with good controllability of film thickness. The i type CIGS layer acts as an i layer since it has a low Cu concentration to adjust a carrier concentration in the film and a small number of carriers.

Although the example of performing the low temperature process step (period 3b) upon completion of the high temperature process step (period 3a) has been illustrated in the above, the present disclosure is not limited thereto. For example, the process is once ended by performing the high temperature process step (period 3a), and after a while, a fraction of Cu may be reduced to form a desired CIGS surface layer while changing a temperature as shown in the period 3b. In addition, although the three-step process has been illustrated, the present disclosure is not limited thereto. For example, a bilayer method may be used to carry out the present disclosure. The bilayer method is a method of forming a CIGS film by means of, for example, an evaporation method, a sputtering method or the like using four elements of Cu, In, Ga and Se in the first step and using three elements of In, Ga and Se except Cu in the subsequent second step. For example, after forming the film by means of the bilayer method, a fraction Cu may be reduced to form the desired CIGS surface layer while changing the temperature in the period 3b. It is to be understood that the present disclosure can be also carried out by performing the above-described low temperature process step (period 3b) for the CIGS thin film prepared using other film forming methods (for example, a sulfurization method, a selenization/sulfurization method, a co-evaporation method, an in-line type co-evaporation method, a fast solid state selenizadon method, an RR (Roll-to-Roll) method, an ionization deposition RR method, a co-deposition deposition RR method, an electrodeposition method, a hybrid process, a hybrid sputter RR method, a nanoparticle printing method, a nanoparticle printing RR method, a FASST® process, etc.).

In the color solid state imaging device which can be applied to the CIGS image sensor 1 for use in the inspection system according to the first or second embodiment, a change in a current value for the presence of light irradiation and the absence of light irradiation under a state where a relatively low target voltage Vt is applied is minute. On the other hand, a change in a current value for the presence of light irradiation and the absence of light irradiation under a state where an avalanche multiplication effect can be produced by application of a relatively high voltage is extremely remarkable. Since a dark current in the absence of light irradiation is substantially the same, a S/N (Signal-to-Noise) ratio is also improved in the color solid state imaging device which can be applied to the CIGS image sensor 1 for use in the inspection system according to the first or second embodiment.

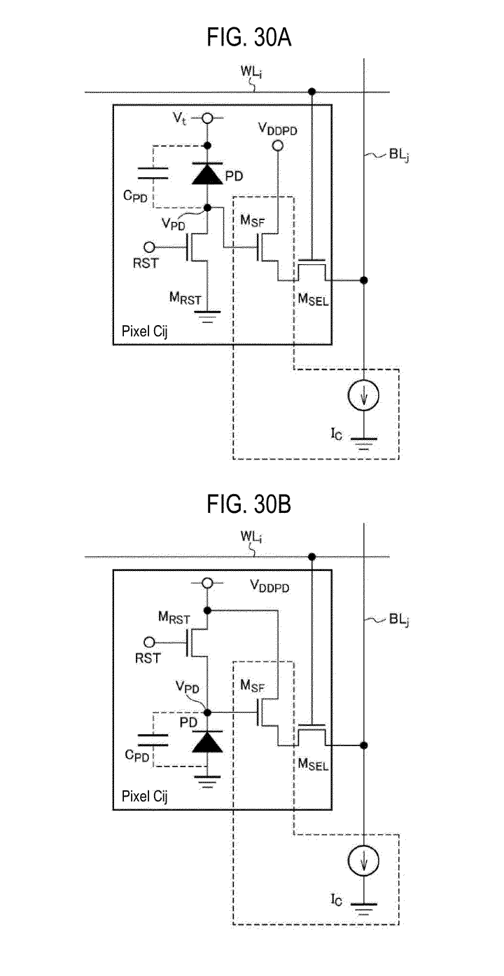

In the case of using avalanche multiplication, a circuit configuration of one pixel Cᵢⱼ of the color solid state imaging device which can be applied to the CIGS image sensor 1 for use in the inspection system according to the first or second embodiment includes a photodiode PD and three MOS transistors M_{SRT}, M_{SF} and M_{SEL}, for example as shown in FIG. 30A. On the other hand, in the case of using no avalanche multiplication, the circuit configuration is, for example, as shown in FIG. 30B.

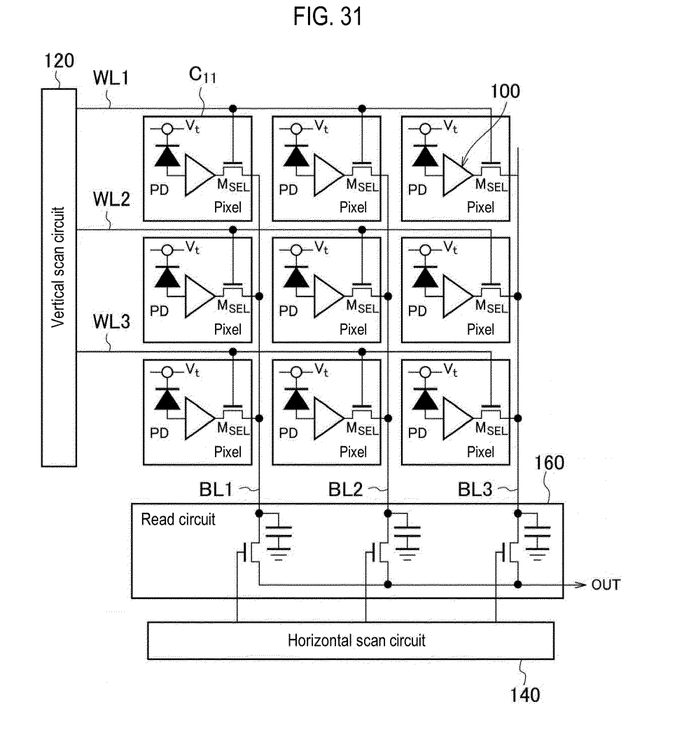

As shown in FIG. 31, the color solid state imaging device which can be applied to the CIGS image sensor 1 for use in the inspection system according to the first or second embodiment includes a plurality of word lines WLᵢ (i=1 to m (m is an integer)) arranged in a row direction, a plurality of bit lines BLⱼ (j=1 to n (n is an integer)) arranged in a column direction, a lower electrode layer 25, a chalcopyrite-structured compound semiconductor thin film 24 disposed on the lower electrode layer 25, photodiodes PD having a transparent electrode layer 26 disposed on the compound semiconductor thin film 24, visible light filters 44R, 44G and 44B disposed on the transparent electrode layer 26, and pixels Cᵢⱼ disposed at intersections of the plurality of word lines WLᵢ and the plurality of bit lines BLⱼ. Although the configuration of FIG. 31 is shown to have a 3×3 matrix, it may be extended to an m×n matrix, as described above. The photodiodes PD correspond to the photo-electric conversion part 28 of FIG. 21.

A circuit configuration of each of the pixels shown in FIG. 31 corresponds to that shown in FIG. 30A. Alternatively, the circuit configuration shown in FIG. 30B may also be employed for each of the pixels. A buffer 100 is a source follower enclosed by a dotted line in FIG. 30A and includes a constant current source Ic and the MOS transistor M_{SF}. A gate of the select MOS transistor M_{SEL} is connected to a word line WLᵢ. A target voltage Vₜ [V] is applied to a cathode of the photodiode PD. A capacitor C_{PD} is a depletion layer capacitance of the photodiode PD and serves to store an electric charge.

A drain of the MOS transistor M_{SF} serving as a source follower is connected to a power supply voltage V_{DDPD}. An anode of the photodiode PD is connected to the MOS transistor M_{RST} for reset and the photodiode PD is reset to an initial state at a timing of a signal input to a reset terminal RST.

According to the first embodiment, since little sensitivity to light in a near-infrared region is provided by controlling the thickness of the compound semiconductor thin film 24, no infrared cutoff filter is needed and it is possible to provide a color solid state imaging device having a high sensitivity in only a visible region.

In the color solid state imaging device which can be applied to the CIGS image sensor 1 for use in the inspection system according to the first or second embodiment, it is possible to control the thickness of the compound semiconductor thin film 24 having visible light sensitivity characteristics suitable for the visible light filters 44R, 44G and 44B by forming a step in the interlayer insulating film 20.

Although a color is adjusted to fit a white balance in order to obtain a color image signal, if an absorbing layer has a sensitivity to light in near infrared region, precise color reproducibility cannot be obtained since the color image signal differs from the color vision characteristics of a human. Accordingly, a signal processing method to cope with this problem is required. However, according to the color solid state imaging device and its modification which can be applied to the CIGS image sensor 1 for use in the inspection system according to the first or second embodiment, such signal processing is unnecessary because the absorbing layer has no sensitivity to light in the near-infrared region.

In the color solid state imaging device which can be applied to the CIGS image sensor 1 for use in the inspection system according to the first or second embodiment, it is possible to realize a configuration where a pixel portion in which the visible light filters 44R, 44G and 44B are arranged absorbs only visible light by controlling the thickness of the compound semiconductor thin film 24.

In the color solid state imaging device which can be applied to the CIGS image sensor 1 for use in the inspection system according to the first or second embodiment, it is possible to realize a configuration where a pixel portion in which the visible light filters 44R, 44G and 44B are arranged absorbs only visible light by controlling the band gap energy Eg of the compound semiconductor thin film 24.

In the color solid state imaging device which can be applied to the CIGS image sensor 1 for use in the inspection system according to the first or second embodiment, it is possible to realize a configuration where a pixel portion in which the visible light filters 44R, 44G and 44B are arranged absorbs only visible light and a pixel portion in which the near-infrared filter 44I is arranged absorbs only near-infrared light by controlling both the thickness and band gap energy Eg of the compound semiconductor thin film 24.

According to the color solid state imaging device and its modification which can be applied to the CIGS image sensor 1 for use in the inspection system according to the first or second embodiment, no infrared removing filter for visual sensitivity correction is needed and it is possible to provide a color solid state imaging device to adjust color reproducibility to the human visual sensitivity.

In the color solid state imaging device and its modification which can be applied to the CIGS image sensor 1 for use in the inspection system according to the first or second embodiment, although Cu(In_{X}, Ga_{1-X})Se₂ (0≦X≦1) is used as the chalcopyrite-structured compound semiconductor thin film 24 for the photo-electric conversion part 28, the present disclosure is not limited thereto.

For a CIGS thin film employed as the compound semiconductor thin film 24, a composition of Cu(In_{X}, Ga_{1-X})(Se_{Y},S_{1-Y})(0≦X≦1 and (0≦Y≦1)) is known in the art, and a CIGS thin film having such a composition may be used.

The chalcopyrite-structured compound semiconductor thin film 24 may employ other different compound semiconductor thin films such as CuAlS₂, CuAlSe₂, CuAlTe₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, AgInTe₂, and the like.

In addition, although the configuration including the buffer layer 36 has been illustrated as an embodiment in the above, the present disclosure is not limited thereto. It may be configured to dispose the transparent electrode layer 26 on the compound semiconductor thin film (CIGS) 24 without the buffer layer 36 interposed therebetween.

In addition, in the color solid state imaging device which can be applied to the CIGS image sensor 1 for use in the inspection system according to the first or second embodiment, although the configuration where the anode of the photodiode constituted by the compound semiconductor thin film 24 is connected to the gate electrode of the MOS transistor of the circuit part 30, i.e., the configuration having the amplification function on a pixel-by-pixel basis, has been mainly described, the present disclosure is not limited to such a configuration s For example, a configuration where the anode of the photodiode is connected to the source or drain electrode of the MOS transistor of the circuit part 30, i.e., a configuration hay g o amplification function on a pixel-by-pixel basis, may be employed.

In addition, in the color solid state imaging device which can be applied to the CIGS image sensor 1 for use in the inspection system according to the first or second embodiment, although the configuration including the avalanche multiplication function in the photodiode constituted by the compound semiconductor thin film 24 has been mainly described, the configuration of the photo-electric conversion part 28 is not limited to the configuration having the avalanche multiplication function. For example, a photodiode constituted by the compound semiconductor thin film 24 having no avalanche multiplication function may be used.

### Other Embodiments

As described above, the present disclosure has been illustrated by way of the first and second embodiments, but the description and drawings which constitute a part of this disclosure are provided by way of example and should not be construed to limit the present disclosure. Various alternative embodiments, examples and operation techniques will be apparent to those skilled in the art from this disclosure.

Thus, the present disclosure encompasses various embodiments which are not described herein. For example, although the inspection is performed by the PC 5 in the first and second embodiments, the inspection apparatus is not limited to the PC 5. For example, the inspection apparatus may include various apparatuses that can communicate with the CIGS camera 6, such as tablet terminals, mobile phones and so on. Of course, if the CIGS camera 6 incorporates the same function as the PC 5, it is possible to work the CIGS camera 6 itself as an inspection apparatus.

The inspection system of the present disclosure can be applied to a solar panel inspection system for inspecting a solar panel, a security camera system for detecting heat, and so on. Moreover, the inspection system of the present disclosure can be applied to other different inspection systems that need to perform an inspecting operation based on a visible light image and an infrared light image.

According to the present disclosure in some embodiments, it is possible to provide an inspection system which is capable of inspecting an inspection object with convenience and high precision, an inspection method, a pixel circuit and an image sensor.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection system comprising:
a CIGS camera configured to generate a visible light image and an infrared light image of an inspection object by imaging visible light and infrared light simultaneously on the same optical axis using a CIGS image sensor; and
an inspection apparatus configured to inspect the inspection object based on the visible light image and the infrared light image.

2. The inspection system of claim 1, wherein the inspection apparatus displays the visible light image and the infrared light image in a superimposing fashion.

3. The inspection system of claim 1, wherein the CIGS camera images electroluminescence light generated by flowing a current into a solar panel, and
wherein the inspection apparatus specifies a position of a defective cell included in the solar panel based on an infrared light image of the solar panel.

4. The inspection system of claim 3, wherein the inspection apparatus inspects the presence of damage to a surface of the solar panel based on a visible light image of the solar panel.

5. The inspection system of claim 1, wherein the CIGS camera images infrared light generated in a hot spot of a specific temperature or higher, and
wherein the inspection apparatus specifies a position of heat generation of the inspection object based on an infrared light image of the inspection object.

6. The inspection system of claim 5, wherein the inspection apparatus outputs a warning for informing a danger if heat is generated from the inspection object.

7. The inspection system of claim 1, wherein, if the inspection object is an LSI, the CIGS camera takes an image from a side of the LSI where no wiring pattern is formed.

8. The inspection system of claim 1, wherein the CIGS image sensor includes a pixel circuit including a photodiode and a floating diffusion, and
wherein the pixel circuit outputs a voltage determined by an electric charge quantity transmitted from a parasitic capacitance of the photodiode to the floating diffusion and a capacitance of the photodiode.

9. The inspection system of claim 8, wherein the pixel circuit includes a transmission transistor to transmit electric charges between the photodiode and the floating diffusion, and a transmission signal line connected to a gate of the transmission transistor, and
wherein the gate of the transmission transistor is controlled by a transmission signal input to the transmission signal line.

10. The inspection system of claim 8, wherein the pixel circuit includes a reset transistor to hold an electric charge of the floating diffusion in an initial state, and a reset signal line connected to a gate of the reset transistor, and
wherein the gate of the reset transistor is controlled by a reset signal input to the reset signal line.

11. The inspection system of claim 8, wherein the pixel circuit includes a buffer transistor to read an electric potential of a specific node, an output transistor to output a read signal to a vertical signal line, and a selection signal line connected to a gate of the output transistor, and
wherein the gate of the output transistor is controlled by a selection signal input to the selection signal line.

12. An inspection method comprising:
generating a visible light image and an infrared light image of an inspection object by imaging visible light and infrared light simultaneously on the same optical axis using a CIGS image sensor; and
inspecting the inspection object based on the visible light image and the infrared light image.

13. A pixel circuit comprising:
a photodiode; and
a floating diffusion,
wherein the pixel circuit outputs a voltage determined by an electric charge quantity transmitted from a parasitic capacitance of the photodiode to the floating diffusion and a capacitance of the photodiode.

14. The pixel circuit of claim 13, further comprising:
a transmission transistor to transmit electric charges between the photodiode and the floating diffusion; and
a transmission signal line connected to a gate of the transmission transistor,
wherein the gate of the transmission transistor is controlled by a transmission signal input to the transmission signal line.

15. The pixel circuit of claim 13, further comprising:
a reset transistor to hold an electric charge of the floating diffusion in an initial state; and
a reset signal line connected to a gate of the reset transistor,
wherein the gate of the reset transistor is controlled by a reset signal input to the reset signal line.

16. The pixel circuit of claim 13, further comprising:
a buffer transistor to read an electric potential of a specific node;
an output transistor to output a read signal to a vertical signal line; and
a selection signal line connected to a gate of the output transistor,
wherein the gate of the output transistor is controlled by a selection signal input to the selection signal line.

17. An image sensor having a pixel circuit performing image sensing on a pixel basis, wherein the pixel circuit includes:
a photodiode; and
a floating diffusion, and
wherein the pixel circuit outputs a voltage determined by an electric charge quantity transmitted from a parasitic capacitance of the photodiode to the floating diffusion and a capacitance of the photodiode.

18. The image sensor of claim 17, wherein the pixel circuit includes:
a transmission transistor to transmit electric charges between the photodiode and the floating diffusion; and
a transmission signal line connected to a gate of the transmission transistor, and
wherein the gate of the transmission transistor is controlled by a transmission signal input to the transmission signal line.

19. The image sensor of claim 17, wherein the pixel circuit includes:
a reset transistor to hold an electric charge of the floating diffusion in an initial state; and
a reset signal line connected to a gate of the reset transistor, and
wherein the gate of the reset transistor is controlled by a reset signal input to the reset signal line.

20. The image sensor of claim 17, wherein the pixel circuit includes:
a buffer transistor to read an electric potential of a specific node;
an output transistor to output a read signal to a vertical signal line; and
a selection signal line connected to a gate of the output transistor, and
wherein the gate of the output transistor is controlled by a selection signal input to the selection signal line.
